(19) United States
(12) Patent Application Publication
(10) Pub. No.: US 2020/0145793 A1
(43) Pub. Date: May 7, 2020

(54) INTERNET OF THINGS (IOT) MESSAGE DISTRIBUTION AND DISPLAY PLATFORM

(71) Applicants: Patrick Coulbourne, Snellville, GA (US); Andrew Young, Snellville, GA (US)

(72) Inventors: Patrick Coulbourne, Snellville, GA (US); Andrew Young, Snellville, GA (US)

(21) Appl. No.: 16/607,485

(22) PCT Filed: Apr. 20, 2018
(86) PCT No.: PCT/US2018/028536

§ 371 Date: Oct. 23, 2019

Related U.S. Application Data
(60) Provisional application No. 62/488,840, filed on Apr. 23, 2017.

(51) Int. Cl. H04W 4/12; H04W 4/02; H01L 33/54; G06Q 30/02

(52) U.S. Cl. CPC H04W 4/12; G06Q 30/0277; H01L 33/54; H04W 4/025

(57) ABSTRACT

An Internet of Things (IoT) Message Distribution and Display Platform for providing a cloud platform or advertisement sharing cloud platform, a cloud and/or mobile software application supporting a portable Internet of Things (IoT) hardware device that displays self-generated and/or self-sourced text, graphics and animations and/or displays text, graphics and animations generated from other users, parties or sources on or outside of the cloud platform as determined by dynamic geographical parameters, personal preferences and/or other means, and may include remuneration and/or compensation to the user for displaying the content and fees and/or payments from the party requesting display of the content.

### CROSS-REFERENCE TO RELATED APPLICATION

This application claims priority to and benefit of U.S. provisional patent application Ser. No. 62/488,840 filed Apr. 23, 2017, which is fully incorporated by reference and made a part hereof.

### FIELD OF THE INVENTION

Embodiments of the present invention relate generally to IoT Message Distribution and Display Devices and more specifically to an Internet of Things (IoT) Message Distribution and Display Platform for providing a cloud platform or advertisement sharing cloud platform, a cloud and/or mobile software application supporting a portable Internet of Things (IoT) hardware device that displays self-generated and/or self-sourced text, graphics and animations and/or displays text, graphics and animations generated from other users, parties or sources on or outside of the cloud platform or advertisement sharing cloud platform as determined by dynamic geographical parameters, personal preferences and/or other means, and may include remuneration and/or compensation to the user for displaying the content and fees and/or payments from the party requesting display of the content.

### BACKGROUND

Display of electronic content is normally available only between devices configured in a stable, predetermined electronic communications network. When electronic content is broadcasted from a central device to receiving device(s) in a persistent connection state, all connected devices receive and display the received content without additional manipulation or processing of the content. Similarly, when electronic content is requested from one or more receiving device(s) configured in a stable, predetermined electronic communications network in a persistent or semi-persistent connection state, the receiving device(s) displays the content broadcasted from the central device without additional further manipulation or processing. In some cases, the content received by each device will be the same or different based on limited, static device parameter(s) sent by the receiving device to the central device at the time of content request.

There is no general method of establishing a dynamic electronic communications network between one or more pairs of sending and receiving devices based on dynamic and/or static device parameters such that the content sent electronically from the sending device to the receiving device is based on the current state of device parameters at the instant of request. Similarly, there is no general method of establishing a dynamic and/or static electronic communications network between one or more pairs of sending and receiving devices such that the electronic content requested by the receiving device from the sending device is based on the current state of device parameters at the instant of request.

Additionally, there is no general method for additional manipulation and/or processing of received content based on the dynamic and/or static parameters of the connected display. Whereas the physical display characteristics of identical content sent to two different receiving devices will differ based on the size, shape, capabilities and current state of the display, the received content and the interpretation of these by the executable program routines on the receiving device.

In terms of the device and display components, there is no general system for the creation of a flexible, addressable light emitted diode (LED) display matrix with different physical characteristics (length, width, density, LED count) and mounting properties based on end use applications. Similarly, there is no general system for a programmed, internet of things (IOT) device to control a connected display; control the receipt and processing of content; and the processing and transmission of device and display information developed in a miniaturized physical footprint.

In general, the current state of the art lacks, inter alia, a system and method for sending and displaying content communicated between one or more pairs of sending and receiving devices configured in a dynamic communications network based on dynamic and/or static parameters shared between the paired devices at the time of transmission; manipulated and processed on a miniaturized internet of things (IOT) device and rendered to a connected flexible addressable light emitted diode (LED) display.

### BRIEF SUMMARY

The invention generally relates to an IoT Message Distribution and Display Device which includes a Cloud Platform (10) which can be extended to included advanced marketplace, scheduling and commerce functionality as described by the Advertisement Sharing Cloud Platform (20). Both of which provide data and internet access, applications, advanced logic and processing capabilities. Connection to the platform is facilitated by a standard IEEE 802.11x (WIFI) Transceiver (46) communicating directly to an Internet of Things (IoT) Hardware System (40), or connection to the platform is facilitated by communicating to a standard Cellular Transceiver (33) or IEEE 802.11x (WIFI) Transceiver (34) onboard a Smart Device (30) and then wirelessly paired to an Internet of Things (IoT) Hardware System (40) via a Bluetooth Low Energy (BLE) Transceiver (32). Both options provide access to the mobile or cloud application, user interface and Machine-to-Machine (M2M) control of the connected Internet of Things (IoT) Hardware System (40) and connected addressable Light Emitted Diode (LED) matrix Display System (60). The Display System (60) can be embodied in multiple variations utilizing different display matrix sizes, form factors and configurations. The Hardware System (40) and Display System (60) are manufactured into the Smooth Surface Mount System (70) for temporary mounting on smooth surfaces or alternatively manufactured into the Metallic Surface Mount System (80) for temporary mounting on metallic surfaces. Both the Smooth Surface Mount System (70) and Metallic Surface Mount Systems (80) provide a variety of optional components that can be incorporated into different configurations that achieve protection and portability requirements based on end-user requirements. In addition to providing different manufactured Display Systems (60) sizes, individual Display Systems (60) can be connected using one or more Display Extension Systems (50) to extend the overall display matrix by enabling disparate Display Systems (60) to operate as a single display matrix. The entire sub-assembly of Hardware System (40), Display System (60), Hardware Case and Mount System (90) and Smooth Surface Mount System (70) or alternatively the Metallic Surface Mount System (80) are embodied in the Assembled Device (100).

There has thus been outlined, rather broadly, some of the features of the invention in order that the detailed description thereof may be better understood, and in order that the present contribution to the art may be better appreciated. There are additional features of the invention that will be described hereinafter.

In this respect, before explaining at least one embodiment of the invention in detail, it is to be understood that the invention is not limited in its application to the details of construction or to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

One object is to provide an Internet of Things (IoT) Message Distribution and Display Platform for providing a cloud platform or advertisement sharing cloud platform, a cloud and/or mobile software application supporting a unique and portable Internet of Things (IoT) hardware device that displays self-generated and/or self-sourced text, graphics and animations and/or displays text, graphics and animations generated from other users, parties or sources on or outside of the cloud platform as determined by dynamic geographical parameters, personal preferences and/or other means, and may include remuneration and/or compensation to the user for displaying the content and fees and/or payments from the party requesting display of the content.

Another object is to provide an Internet of Things (IoT) Message Distribution and Display Platform that displays self-generated and/or self-sourced text, graphics and animations (content), the display effects, timing and other aspects of which are governed by saved or interactive parameters available and controlled by the user.

Another object is to provide an Internet of Things (IoT) Message Distribution and Display Platform that displays text, graphics and/or animations (content) generated from other users, parties and/or sources on or outside of the cloud platform, the display effects, timing and other aspects of which are governed by saved parameters included with the content to be displayed.

Another object is to provide an Internet of Things (IoT) Message Distribution and Display Platform that utilizes saved or interactive user-defined parameters that control specific digital characteristics of the text, graphics and animations (content); including but not limited to the timing, duration, actions and characteristics of the content.

Another object is to provide an Internet of Things (IoT) Message Distribution and Display Platform that provides an interface on which users interactively manipulate parameters to control the digital characteristics of the text, graphics and animations (content); including but not limited to the timing, duration, actions and characteristics of the content; as well as where, when and how (scheduling) content is displayed.

Another object is to provide an Internet of Things (IoT) Message Distribution and Display Platform that provides an interface on which users can interactively control parameters around scheduling the display of content immediately or in the future including, but not limited to using date, day and time parameters to control what date, days of the week and time of the day content is displayed; geographical and location parameters to control where content is displayed (including, but not limited to latitude/longitude, city, county, state, region, country) and whether content is displayed on a single or multiple display; and duration and frequency parameters to control the number of times the content is repeated and displayed on one or more displays.

Another object is to provide an Internet of Things (IoT) Message Distribution and Display Platform that provides a billing and payment matrix for the display of content based on, but not limited to geographic, time and business parameters; a content tracking and reconciliation schema, billing and payment engine; and an interactive user interface for scheduling, tracking, confirmation, payment and billing, and history.

Another object is to provide an Internet of Things (IoT) Message Distribution and Display Platform that tracks, logs and saves a history of all content displayed across the entire cloud platform identifying the entity that created and initiated the content display and the user that displayed the content, by user and over time for reporting, payment and billing, customer support and data mining purposes.

Another object is to provide an Internet of Things (IoT) Message Distribution and Display Platform that provides a unique security hardware architecture that protects all IoT software and hardware components, a unique security operating architecture for encrypting/unencrypting data packets, monitoring and controlling data integrity and packet traffic across the entire loud platform.

Another object is to provide an Internet of Things (IoT) Message Distribution and Display Platform that is embodied by a flexible, encapsulated, variable length and width, addressable light-emitted diode (LED) array.

Another object is to provide an Internet of Things (IoT) Message Distribution and Display Platform that enables changing the total count, spacing and placement parameters of addressable light-emitted diode (LED) array to varied totals and configurations during the manufacturing process based on end-application requirements.

Another object is to provide an Internet of Things (IoT) Message Distribution and Display Platform that enables changing the encapsulation substrate material(s) type, composition and parameters securing, encasing, protecting and supporting the addressable light-emitted diode (LED) array during the manufacturing process based on end-application requirements.

Another object is to provide an Internet of Things (IoT) Message Distribution and Display Platform that enables connecting the power and data from multiple displays together thus resulting in a master/slave relationship where the data connection is shared and content is displayed seamlessly across multiple, disparate displays.

Another object is to provide an Internet of Things (IoT) Message Distribution and Display Platform that operates the hardware, display and software at a low voltage and through on board standard power shifting hardware to support multiple power sources, including standard wall and vehicle receptacles, and a range of battery voltages from 5V-24V.

Another object is to provide an Internet of Things (IoT) Message Distribution and Display Platform that is embodied by a unique scalable, display power architecture.

Another object is to provide an Internet of Things (IoT) Message Distribution and Display Platform that provides Internet of Things (IoT), Machine-2-Machine (M2M) communication capabilities, advanced networking capabilities and autonomous communication transceiver switching via on-board IEEE802.11x (WIFI) and Bluetooth Low Energy (BLE) transceivers.

Another object is to provide an Internet of Things (IoT) Message Distribution and Display Platform that is embodied by a commercially available micro-controller unit (MCU) connected directly to a display and with Internet of Things (IoT) capability for the transmission and receipt of message packets (content and commands) via on-board IEEE802.11x (WIFI) and/or Bluetooth Low Energy (BLE) transceivers.

Another object is to provide an Internet of Things (IoT) Message Distribution and Display Platform that is embodied by multiple unique integrated mounting systems each with the ability to mount temporarily to multiple external surfaces as dictated by end-application requirements.

Another object is to provide an Internet of Things (IoT) Message Distribution and Display Platform that is embodied by a unique interconnecting display system that enables multiple individual Display Systems to be linked together in width and/or in height directions to create a uniquely sized modular display assembly that functions as a single displaying unit.

Another object is to provide an Internet of Things (IoT) Message Distribution and Display Platform that is embodied by a modular display assembly design that can increase the overall display area beyond a single display size based on end-application requirements.

Another object is to provide an Internet of Things (IoT) Message Distribution and Display Platform that providing a means to display safety, distress, entertainment, logistics, information or other content on a non-rigid, portable display in any environment to achieve a specific need, goal or application.

Another object is to provide an Internet of Things (IoT) Message Distribution and Display Platform that providing a means for individuals and/or businesses to display advertisements which are a sequenced combination of text, graphics and animation (content) on a non-rigid, portable display in any environment.

Another object is to provide an Internet of Things (IoT) Message Distribution and Display Platform that providing a platform for individuals and other individuals and/or business to interact and transact based on multiple parameters with the intent to display text, graphics and animations (content) on a non-rigid, portable display in any environment for compensation and/or monetary fee.

Another object is to provide an Internet of Things (IoT) Message Distribution and Display Platform that provides a means to temporarily mount the display including, but not limited to using a unique suction cup mounting system supporting the weight of the display unit on a smooth surface; or a magnetic mounting system supporting the weight of the display unit on a metallic surface.

Other objects and advantages will become apparent to the reader and it is intended that these objects and advantages are within the scope of the present invention. To the accomplishment of the above and related objects, this invention may be embodied in the form illustrated in the accompanying drawings, attention being called to the fact, however, that the drawings are illustrative only, and that changes may be made in the specific construction illustrated and described within the scope of this application.

### BRIEF DESCRIPTION OF THE DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

FIG. 1 is an overall block diagram illustrating aspects of embodiments of the present invention. The block diagram illustrates of an example of an overall Cloud Platform (10), hardware and mobile software application solution according to some embodiments for facilitating hardware component control and data connectivity between a Display System (60), Hardware System (40) and Cloud Platform (10) such that hardware component control and data connectivity to/from the Cloud Platform (10) is through a single, paired connection through a Smart Device (30) and controlled by a mobile application resident on the Smart Device (30). The Assembled Device (100) is the assembly of the Hardware System (40), Display System (60), Hardware Case and Mount System (90) and Smooth Surface Mount System (70) or Metallic Surface Mount System (90).

FIG. 2 is a block diagram of an alternative embodiment. The block diagram illustrates of an example of an overall Advertisement Sharing Cloud Platform (20), hardware and mobile software application solution according to some embodiments for facilitating hardware component control and data connectivity between a Display System (60), Hardware System (40) and Advertisement Sharing Cloud Platform (20) such that hardware component control and data connectivity to/from the Advertisement Sharing Cloud Platform (20) is through a single, paired connection through a Smart Device (30) and controlled by a mobile application resident on the Smart Device (30). The Assembled Device (100) is the assembly of the Hardware System (40), Display System (60), Hardware Case and Mount System (90) and Smooth Surface Mount System (70) or Metallic Surface Mount System (90).

FIG. 3 is a block diagram illustrating an overall Cloud Platform (10), hardware and cloud or mobile software application solution according to some embodiments for facilitating hardware component control and data connectivity between a Display System (60), Hardware System (40) and Cloud Platform (10) such that hardware component control and data connectivity to/from the Cloud Platform (10) can include multiple data connection paths through a Smart Device (30) or directly between the Hardware System (40) and the Cloud Platform (10) and controlled by a cloud or mobile application resident on the Smart Device (30) or on the Cloud Platform (10). The Assembled Device (100) is the assembly of the Hardware System (40), Display System (60), Hardware Case and Mount System (90) and Smooth Surface Mount System (70) or Metallic Surface Mount System (90).

FIG. 4 is an alternative embodiment illustrating an example of an overall Advertisement Sharing Cloud Platform (20), hardware and cloud or mobile software application solution according to some embodiments for facilitating hardware component control and data connectivity between a Display System (60), Hardware System (40) and Advertisement Sharing Cloud Platform (20) such that hardware component control and data connectivity to/from the Advertisement Sharing Cloud Platform can include multiple data connection paths through a Smart Device (30) or directly between the Hardware System (40) and the Advertisement Sharing Cloud Platform (20) and controlled by a cloud or mobile application resident on the Smart Device (30) or on the Advertisement Sharing Cloud Platform (20). The Assembled Device (100) is the assembly of the Hardware System (40), Display System (60), Hardware Case and Mount System (90) and Smooth Surface Mount System (70) or Metallic Surface Mount System (90).

FIG. 5 is a block diagram illustrating an example of a Cloud Platform (10) required to communicate with external Assembled Device (100) including an Internet of Things (IoT) devices; register, secure and manage display devices; register and manage user accounts; secure data communications and transmissions; and manage utility, Machine-2-Machine (M2M) and user-facing cloud and mobile applications, according to some embodiments.

FIG. 6 is a block diagram illustrating an example of an Advertisement Sharing Cloud Platform (20) required to communicate with external Assembled Device (100) including an Internet of Things (IoT) devices; register, secure and manage display devices; match, connect and track advertisement content with display devices; facilitate and reconcile billing and payments for users and advertisers; schedule, track and log advertisements; register and manage user accounts; secure data communications and transmissions; and manage utility, Machine-2-Machine (M2M) and user-facing cloud and mobile applications, according to some embodiments.

FIG. 7 is a block diagram illustrating an example of a commercially available Smart Device (30) with onboard hardware components required to establish and sustain a connection with external Bluetooth Low Energy (BLE) paired devices; and/or establish and sustain a connection with external IEEE 802.11x (WIFI) connected devices.

FIG. 8 is a block diagram an example of a Hardware System (40) and supporting software system for controlling connected Display Systems (60), connecting and communicating to external devices and Cloud Platforms (10) or Advertisement Sharing Cloud Platforms (20) via Bluetooth Low Energy (BLE) Transceiver (42), processing internal and external commands and managing power input and output, according to some embodiments.

FIG. 9 is an alternative embodiment illustrated by an example of a Hardware System (40) and supporting software for controlling connected Display Systems (60), connecting and communicating to external devices and Cloud Platforms (10) or Advertisement Sharing Cloud Platforms (20) via Bluetooth Low Energy (BLE) Transceiver (42) and/or IEEE 802.11x (WIFI) Transceiver (46), processing internal and external commands, and managing power input and output, according to some embodiments.

FIG. 10 is a block diagram illustrating an example of a Display Extension System (50) for temporarily connecting and controlling multiple Display Systems (60) into a single functioning display unit using multiple Display Extension Systems (50) to provide power and data management, according to some embodiments.

FIG. 11 is an exploded side view illustrating an example of a system illustrating multiple options for attaching multiple Display Systems (60) together using Display Extension Systems (50) to temporarily extend the display horizontally, vertically or both to create a single functioning display unit, according to some embodiments.

FIG. 12 is an upper perspective view illustrating an example of the Display Extension Hardware Case (57) for a protective case for Display Extension System (50) hardware components and mating connections to the Female Hardware Connection Ports In (77, 78) and Female Display Extension Connection Ports Out (83, 84) on the Smooth Surface Mount System (70) and Metallic Surface Mount System (80), according to some embodiments.

FIG. 13 is a block diagram illustrating an example of a Display System (60) sub-component hardware system including an Addressable Light Emitted Diode (LED) Array (61) connected by a Conductive Medium (62), sandwiched between two Mounting Substrate A and B (64, 65), manufactured into a Display Mounting System (66) and providing Hardware System Wiring Interfaces In and Out (67, 68) according to some embodiments.

FIG. 14 is an exploded side view illustrating an example of a system for creating an Addressable Light Emitted Diode (LED) (61) array of any overall width and length depending on application requirements and connected by a Conductive Medium (62) depending on application requirements for the Display Array (63), according to some embodiments.

FIG. 15 is an exploded side view illustrating an example of a system for spacing individual Addressable Light Emitted Diode (LED) (61) at any distance in columns and rows depending on application requirements and connected by a Conductive Medium (62) depending on application requirements for the Display Array (63), according to some embodiments.

FIG. 16 is an exploded side view illustrating a method of a system for sandwiching a completed Display Array (63) between two Mounting Substrates A and B (64, 65) depending on application requirements for the Display Mounting System (66), according to some embodiments.

FIG. 17 is an exploded side view illustrating a method of a system for mounting a completed Display Array (63) suspended in one or more Mounting Substrate (64, 65), the horizontal and vertical border variables required, and overall height, width and thickness of the overall mounting substrate depending on application requirements for the Display Mounting System (66), according to some embodiments.

FIG. 18 is a block diagram illustrating a method of a system for providing multiple options of mounting a Display System (60), a protective case for housing Hardware System (40) components and an External Mounting Interface (74) and system for mounting to an external smooth surface, according to some embodiments.

FIG. 19 is an upper perspective view illustrating an example of the Combination End Cap and Mounting Interface (71) for a Display System (60), a protective case for housing Hardware System (40) components and an External Mounting Interface (74) and system for mounting to an external smooth surface, according to some embodiments.

FIG. 20 is an upper perspective view illustrating an example of the Standard End Cap and Mounting System (72) for a Display System (60) and an External Mounting Interface (74) and system for mounting to an external smooth surface, according to some embodiments.

FIG. 21 is an upper perspective view illustrating an example of the Top and Bottom Mounting Interface (73) for a Display System (60) and an External Mounting Interface (74) and system for mounting to an external smooth surface, according to some embodiments.

FIG. 22 is a block diagram illustrating an example of an External Mounting Interface (74) and system for mounting to an external smooth surface, according to some embodiments.

FIG. 23 is an alternative embodiment illustrating a method of a system for mounting a Display System (60), a protective case for housing the Hardware System (40) and components and an external interface and system for mounting to an external metallic surface, according to some embodiments.

FIG. 24 is an upper perspective view illustrating an example of the Standard End Cap (81) for securing and protecting a Display System (60) and Magnetic Substrate (82), and providing access for connection to a Hardware Case and Mounting System (90) depending on application requirements, according to some embodiments.

FIG. 25 is an exploded side view illustrating a method of a system for adhering a completed Display System (60) and Magnetic Substrate (82) depending on application requirements, according to some embodiments.

FIG. 26 is a block diagram illustrating an example of a Hardware Case and Mounting System (90) required to secure the Hardware System (40) and connection to the Smooth Surface Mount System (70) or Metallic Surface Mount System (80) depending on application requirements, according to some embodiments.

FIG. 27 is an upper perspective view illustrating an example of the Standard Hardware Case (91) for securing and protecting a Hardware System (40) and connection to the Smooth Surface Mount System (70) or Metallic Surface Mount System (80) depending on application requirements, according to some embodiments.

FIG. 28 is a flowchart illustrating an example of a process for dynamically determining the grid map pattern (e. G. Total columns and total rows) using a unique Dynamic Grid Map Sizing algorithm; overlaying a dynamic color matrix and mapping to grid using a unique Dynamic Position/Color Map algorithm and according to some embodiments.

FIG. 29 is a flowchart illustrating an example of a process for creating and editing text using a unique WYSIWYG Text algorithm for producing WYSIWYG (what you see is what you get) text and selecting user controlled text effects including, but not limited to size, rotation, speed, flashing, inversion, freeze and others on a display according to some embodiments.

FIG. 30 is a flowchart illustrating an example of a process for creating and editing a graphics element using a unique Feather Mode Graphics algorithm for producing interactive graphics where changes are sent to a display with each keystroke according to some embodiments.

FIG. 31 is a flowchart illustrating an example of a process for loading a graphics element using a unique WYSIWYG Graphics algorithm for producing WYSIWYG (what you see is what you get) graphics to a display according to some embodiments.

FIG. 32 is a flowchart illustrating an example of a process for loading text or graphics elements into an asynchronous sequencer to produce a unique variable length, multi-element animation according to some embodiments.

FIG. 33 is a flowchart illustrating an example of a process for polling user display IDs and geographic locations based on certain user inputs to create a dynamic listing of geographically dispersed broadcasting locations (displays) using a unique Map Broadcast Spots algorithm according to some embodiments.

FIG. 34 is a flowchart illustrating an example of a process for loading a dynamic listing of geographically dispersed advertisements based on certain criteria and using a unique Match Advertisements algorithm to match advertisement and locations and transmit advertisement display elements to the matched user device for display according to some embodiments.

FIG. 35 is a flowchart illustrating an example of a process for displaying an advertisement element according to some embodiments.

FIG. 36 is a flowchart illustrating an example of a post advertisement airing process for updating user payments, advertiser billing, advertisement counters and scheduling confirmation according to some embodiments.

FIG. 37 is a flowchart illustrating an example of a process for generating a unique device identification code using a unique Generate Certification ID algorithm according to some embodiments.

FIG. 38 is a flowchart illustrating an example of a process for setting up and changing a unique security PIN code according to some embodiments.

FIG. 39 is a flowchart illustrating an example of a process and situations required for entering a unique security PIN code and the unique Enter PIN algorithm used to test and validate the user input according to some embodiments.

FIG. 40 is a flowchart illustrating an example of a process for recovering the security PIN code according to some embodiments.

FIG. 41 illustrates an exemplary computer or computing device that may comprise all or a portion of the cloud platform (10), the smart device (30), the hardware system (40) and the display system (60).

### DETAILED DESCRIPTION

Before the present methods and systems are disclosed and described, it is to be understood that the methods and systems are not limited to specific synthetic methods, specific components, or to particular compositions. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes¬from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described below with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, can be implemented by computer program instructions. These computer program instructions may be loaded onto a general purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions.

The present methods and systems may be understood more readily by reference to the following detailed description of preferred embodiments and the Examples included therein and to the Figures and their previous and following description.

### A. Overview

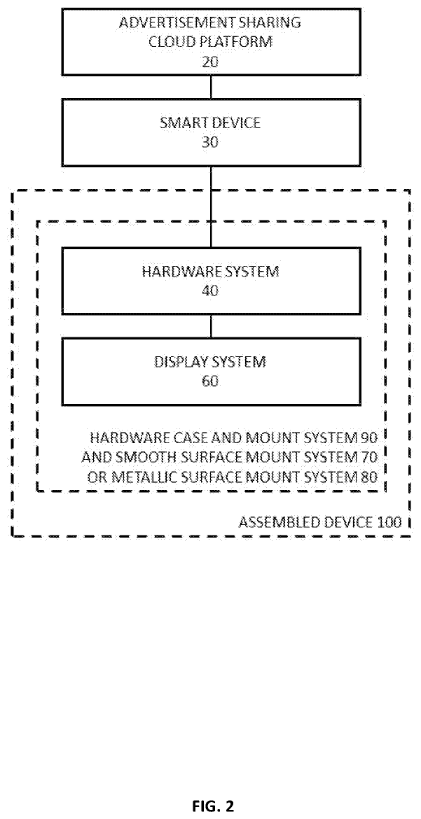

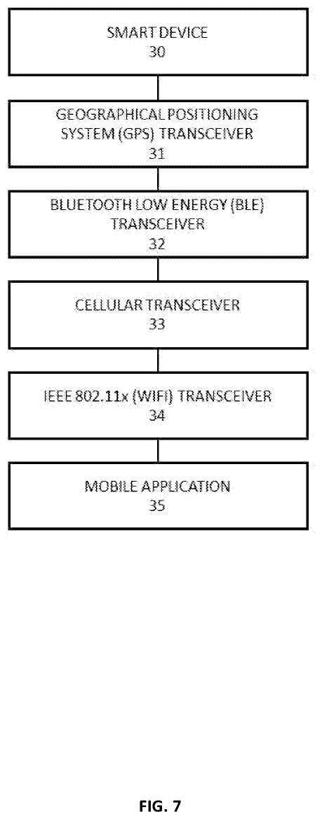

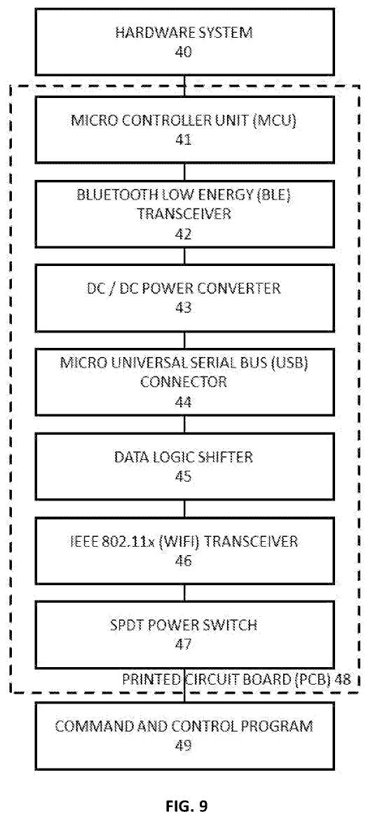

Turning now descriptively to the drawings, in which similar reference characters denote similar elements throughout the several views, the figures illustrate a Cloud Platform (10) which can be extended to included advanced marketplace, scheduling and commerce functionality as described by the Advertisement Sharing Cloud Platform (20, FIG. 2). Both of which provide data and internet access, applications, advanced logic and processing capabilities. Connection to the platform is provided by, for example, an IEEE 802.11x (WIFI) Transceiver (46, FIG. 9) communicating directly to an Internet of Things (IoT) Hardware System (40), or connection to the platform is provided by communicating to a cellular transceiver (33, FIG. 7) or IEEE 802.11x (WIFI) Transceiver (34, FIG. 7) onboard a Smart Device (30) and then wirelessly paired to an Internet of Things (IoT) Hardware System (40) via a Bluetooth Low Energy (BLE) Transceiver (32, FIG. 7). Both options provide access to the mobile or cloud application, user interface and Machine-to-Machine (M2M) control of the connected Internet of Things (IoT) Hardware System (40) and connected addressable Light Emitted Diode (LED) matrix Display System (60). The Display System (60) can be embodied in multiple variations utilizing different display matrix sizes, form factors and configurations.

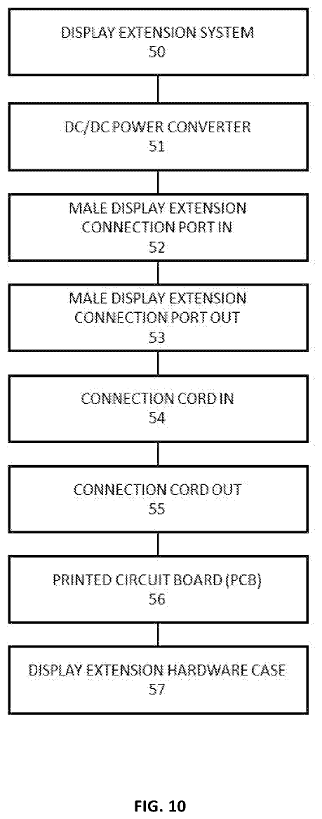

In one aspect, the Hardware System (40) and Display System (60) are configured into a Smooth Surface Mount System (70) for temporary mounting on smooth surfaces or alternatively, a Metallic Surface Mount System (80) for temporary mounting on metallic surfaces. Both the Smooth Surface Mount System (70) and Metallic Surface Mount Systems (80) provide a variety of optional components that can be incorporated into different configurations that achieve protection and portability requirements based on end-user requirements. In addition to providing different manufactured Display Systems (60) sizes, individual Display Systems (60) can be connected using one or more Display Extension Systems (50, FIG. 10) to extend the overall display matrix by enabling a plurality of Display Systems (60) to operate as a single display matrix. The entire sub-assembly of Hardware System (40), Display System (60), Hardware Case and Mount System (90), Hardware Case and Mount System (90) and Smooth Surface Mount System (70) or alternatively the Metallic Surface Mount System (80) are embodied in the Assembled Device (100).

### B. Cloud Platform

The Cloud Platform (10) comprises an internet-based collection of rules, algorithms, security protocols, applications, databases, user accounts and device data hosted on a secure private server and accessible through a browser using, for example, a registered user account and password (PIN).

In one aspect, the Cloud Platform (10) utilizes the rules, algorithms, security protocols, applications, and databases to interface, communicate and control from a remote location, an individual, extended or group of Internet of Things (IoT) connected display devices characterized by an Assembled Device (100), including a Hardware System (40), Display System (60), Hardware Case and Mount System (90) Smooth Surface Mount System (70), or Metallic Surface Mount System (80) and a Smart Device (30). Optionally or alternatively, another function of the Cloud Platform (10) is to create a persistent, digital connection to the Smart Device (30) via Cellular Transceiver (33) or IEEE 802.11x (WIFI) Transceiver (34) to provide bi-directional data, application and security to the user. Optionally or alternatively, yet another function of the Cloud Platform (10), in some cases, is to create a direct persistent, digital connection to the Hardware System (40) via IEEE 802.11x (WIFI) Transceiver (46) to provide bi-directional data, application and security to the user. Optionally or alternatively, the Cloud Platform (10) is used to control and communicate with individual, extended or groups of Display Systems (60) indirectly through the direct data connection to the Hardware System (40) and/or data connection to the Smart Device (30) as described above. The Cloud Platform (10) is virtually connected (i.e., wirelessly connected in a persistent or semi-persistent state) to the Hardware System (40) and/or the Smart Device (30).

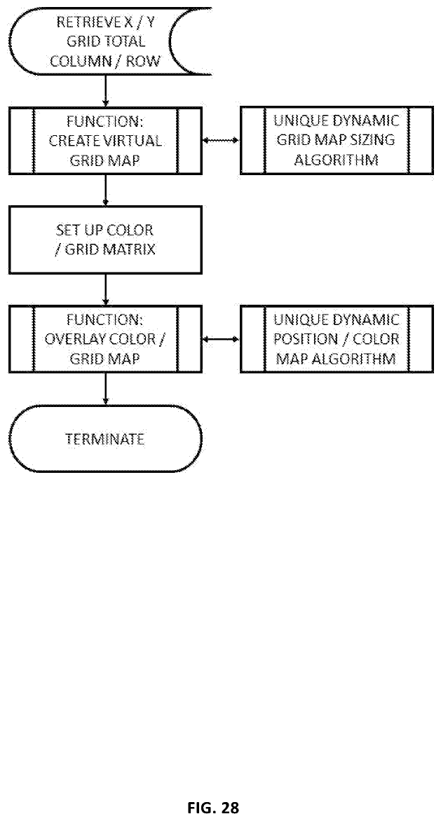

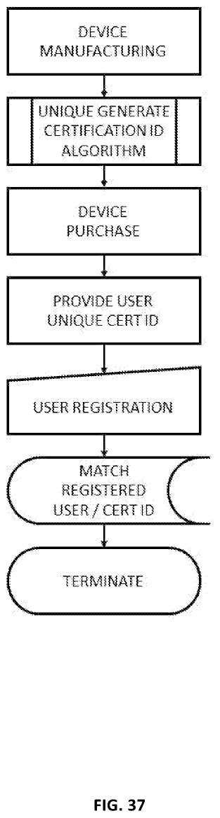

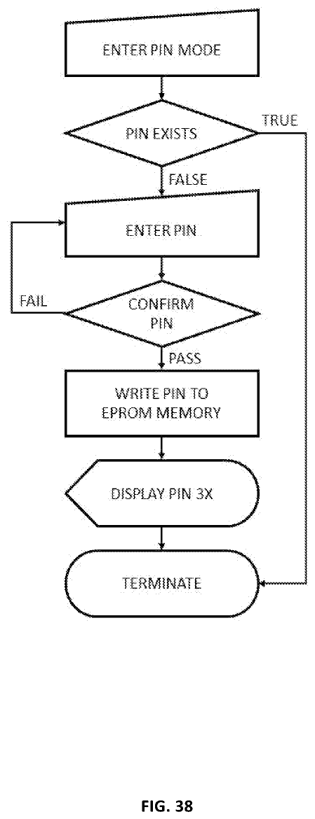

As previously maintained, the Cloud Platform (10) can be accessed by a User (13) through, for example, a user account and password (PIN). The Cloud Platform (10) can also be accessed by individual Devices (14) through a Machine-to-Machine (M2M) interface. The registration of the Devices (14) and establishment of an account and password (PIN) for Users (13) is outlined in FIG. 37. Once established, the user account and password (PIN) can be entered, changed and retrieve as outlined in FIG. 38-FIG. 40. A Security (12) framework and algorithms manages unauthorized Machine-to-Machine (M2M) and user access as outlined in FIG. 37-FIG. 40, as well as data security management, data transmission and communications security. A collection of Applications (15) to support the Users (13) with communication and control of the Assembled Device (100) reside on the Cloud Platform (10); and FIG. 28-FIG. 32 outline controlling text, graphics and animation elements on the Display System (60). The Cloud Platform (10) also maintains the User Interface (11) and delivers on-demand to the Users (13) through a rich browser and presentation layer.

A functional variation of the Cloud Platform (10), is a persistent, digital connection providing bi-directional data, application and security to the user can be established between the Cloud Platform (10) and the Smart Device (30) or Hardware System (40) depending on the transceiver hardware present and available. Specifically, the connection can be facilitated through use of the Cellular Transceiver (33) or the IEEE 802.11x (WIFI) Transceiver (34) onboard the Smart Device (30), or the IEEE 802.11x (WIFI) Transceiver (46) onboard the Hardware System (40). Machine-to-Machine (M2M) logic and algorithms govern and automate this process. A second functional variation of the Cloud Platform (10) is that the connection includes direct Peer-to-Peer (P2P) communication capability between multiple Hardware Systems (40) wherein IEEE 802.11x (WIFI) Transceivers (46) onboard multiple Hardware System (40) share and relay information and commands from the Cloud Platform (10). A third functional variation of the Cloud Platform (10) is that it dynamically assigns one or more Hardware System (40) in a group of Hardware Systems (40) as a host Peer-to-Peer (P2P) connection, sending packets of information and commands relating to the entire group of Hardware Systems (40) to the designated single or multiple Hardware Systems (40) for local distribution to the remaining group. Utilizing this Peer-to-Peer (P2P) framework results in sending portions of content or entire functionality for User Interface (11), Security (12), Users (13), Devices (14) and Application (15) to the Hardware System (40), thus supporting fully connected, semi-connected or disconnected states.

### C. Advertisement Sharing Cloud Platform

The Advertisement Sharing Cloud Platform (20) is an internet-based collection of rules, algorithms, security protocols, applications, databases, user accounts, device data, advertisements, scheduling data, billing and payments data hosted on a secure private server and accessible through a browser using, for example, a registered user account and password (PIN).

The Advertisement Sharing Cloud Platform (20) utilizes the rules, algorithms, security protocols, applications, databases, user accounts, device data, advertisements, scheduling data, billing and payments data to interface, communicate and control, from a remote location an individual, extended or group of Internet of Things (IoT) connected display devices characterized by an Assembled Device (100), including a Hardware System (40), Display System (60), Hardware Case and Mount System (90), Smooth Surface Mount System (70), or Metallic Surface Mount System (80) and a Smart Device (30). The Advertisement Sharing Cloud Platform (20) also provides a marketplace for advertisers to utilize user display devices, facilitate the uploading, scheduling and transmission of advertisement content, capture data from user devices to facilitate billing and payments, usage and other data. The Advertisement Sharing Cloud Platform (20) creates a persistent, digital connection to the Smart Device (30) via Cellular Transceiver (33) or IEEE 802.11x (WIFI) Transceiver (34) to provide bi-directional data, application and security to the user. Optionally or alternatively, the Advertisement Sharing Cloud Platform (20) also creates a direct persistent, digital connection to the Hardware System (40) via IEEE 802.11x (WIFI) Transceiver (46) to provide bi-directional data, application and security to the user. Further, the Cloud Platform (10) controls and communicates with individual, extended or groups of Display System (60) indirectly through the direct data connection to the Hardware System (40) and/or data connection to the Smart Device (30), as described above. The Advertisement Sharing Cloud Platform (20) is virtually connected to the Hardware System (40) and/or the Smart Device (30).

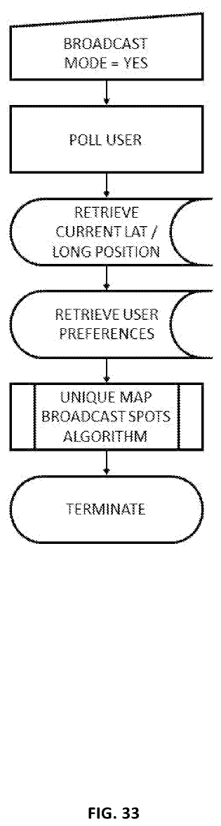

As previously maintained, the Advertisement Sharing Cloud Platform (20) can be accessed by a User (23) through, for example, a user account and password (PIN). The Advertisement Sharing Cloud Platform (20) can also be accessed by individual Devices (24) through a Machine-to-Machine (M2M) interface. The registration of the Devices (24) and establishment of an account and password (PIN) for Users (23) is outlined in FIG. 37. Once established, the user account and password (PIN) can be entered, changed and retrieve as outlined in FIG. 38-FIG. 40. A Security (22) framework and algorithms manages unauthorized Machine-to-Machine (M2M) and user access as outlined in FIG. 37-FIG. 40, as well as data security management, data transmission and communications security. A collection of Applications (25) to support the Users (23) with communication and control of the Assembled Device (100) reside on the Advertisement Sharing Cloud Platform (20); and FIG. 28-FIG. 32 outline controlling text, graphics and animation elements on the Display System (60). The Advertisement Sharing Cloud Platform (20) also maintains the User Interface (21) and delivers on-demand to the Users (23) through a rich browser and presentation layer. In addition, the Advertisement Sharing Cloud Platform (20) includes a specific user group for Advertisers (29), which includes content creators, brokers, advertisers. The Advertisement Sharing Cloud Platform (20) includes a specific content object called Advertisements (25) which are preconfigured and saved groupings of text, graphics and animation elements to control and display on the Display System (60). The Advertisement Sharing Cloud Platform (20) includes additional fields in the Users (23), Advertisers (29), Advertisements (25) to fulfill Billing and Payments (27) and Scheduling (26) requirements. The Advertisement Sharing Cloud Platform (20) includes additional Applications (28) and User Interfaces (21) for completion of the advertisement functions as outlined in FIG. 33-FIG. 36.

Optionally or alternatively, the Advertisement Sharing Cloud Platform (20), comprises a persistent, digital connection providing bi-directional data, application and security to the user can be established between the Advertisement Sharing Cloud Platform (20) and the Smart Device (30) or Hardware System (40), depending on the transceiver hardware present and available. Specifically, the connection can be facilitated through use of the Cellular Transceiver (33) or the IEEE 802.11x (WIFI) Transceiver (34) onboard the Smart Device (30), or the IEEE 802.11x (WIFI) Transceiver (46) onboard the Hardware System (40). Machine-to-Machine (M2M) logic and algorithms govern and automate this process. Optionally or alternatively, the Advertisement Sharing Cloud Platform (20) connection includes direct Peer-to-Peer (P2P) communication capability between multiple Hardware Systems (40), wherein, IEEE 802.11x (WIFI) Transceivers (46) onboard multiple Hardware Systems (40) share and relay information and commands from the Advertisement Sharing Cloud Platform (20). Optionally or alternatively, the Advertisement Sharing Cloud Platform (20) dynamically assigns one or more Hardware System (40) in a group of Hardware Systems (40) as a host Peer-to-Peer (P2P) connection, sending packets of information and commands relating to the entire group of Hardware Systems (40) to the designated single or multiple Hardware Systems (40) for local distribution to the remaining group. Utilizing this Peer-to-Peer (P2P) framework results in sending portions of content or entire functionality for User Interface (21), Security (22), Users (23), Devices (24), Advertisements (25), Scheduling (26), Billing and Payments (27), Advertisers (29) and Application (28) to the Hardware System (50), thus supporting fully connected, semi-connected or disconnected states.

### D. Smart Device

The Smart Device (30) is any device having minimum hardware requirements of Bluetooth 3.0 or greater, IEEE 802.11x (WIFI) or compatible version, accessible WIFI network and/or active cellular service with a minimum 10 MB data package; minimum Operating System (OS) of Android 4.0, Apple iOS 4.2 or Microsoft Mobile 10; and the available storage capability to install and operate a 1 MB application. Non-limiting examples include Apple iPhone™, Samsung Galaxy™, and the like.

The Smart Device (30) is used to connect with and transfer commands and data between the Cloud Platform (10) or Advertisement Cloud Platform (20) and the Hardware System (40). Another function of the Smart Device (30) is to provide security and user application to indirectly interface, communicate and control the Display System (60) through the Hardware System (40). The Smart Device (30) also provides a user interface and application that requires a registered user account and password (PIN) to connect wirelessly to the Hardware System (40), Cloud Platform (10) and/or Advertisement Sharing Cloud Platform (20) through a secure connection which must be established/reestablished and maintained to enable proper performance. The Smart Device (30) is virtually connected to the Cloud Platform (10) or Advertisement Sharing Cloud Platform (20) and the Hardware System (40).

The Smart Device (30) is illustrated by the block diagram in FIG. 7 and comprises a device having minimum hardware requirements of a Geographical Positioning System (GPS) Transceiver (31) for determining user and device locations; Bluetooth Low Energy (BLE) Transceiver (32) for wireless communications with the Hardware System (40) and Display System (60); and Cellular Transceiver (33) and IEEE 802.11x (WIFI) Transceiver (34) for communications with the Cloud Platform (10) or Advertisement Sharing Cloud Platform (20) via the Mobile Application (35).

The Smart Device (30) can vary by commercial manufacturer and SKU. Any commercial device that satisfies the above hardware, software and operating system (OS) requirements is supported.

### E. Hardware System

The Hardware System (40) comprises a set of integrated circuits and components placed on a custom rigid or flexible printed circuit board (PCB). The integrated circuits include power management, data management, communications, program logic, memory, storage and external data and power connections.

The Hardware System (40) provides a bi-directional data connection between the Smart Device (30), Cloud Platform (10) or Advertisement Sharing Cloud Platform (20) and the Display System (60). The Hardware System (40) also receives data from the Cloud Platform (10) or Advertisement Sharing Cloud Platform (20) and using onboard algorithms, logic and compiled statements to command and control the Display System (60). Optionally or alternatively, the Hardware System (40) provides power management and physical connection to the Display System (60), external interface and physical connection to multiple, different external power sources and power switching. Optionally or alternatively, the Hardware System (40) controls one or more additional Display Systems (60) temporarily mated with one or more Display Extension Systems (50). Optionally or alternatively, the Hardware System (40) assembles as a local, dynamic Peer-to-Peer (P2P) network group and acts on behalf of the other Hardware Systems (40) in P2P group sending packets of information and commands relating to the entire group of Hardware Systems (40) to the designated single or multiple Hardware Systems (40) for local distribution to the remaining group. Utilizing this Peer-to-Peer (P2P) framework results in sending portions of content or entire functionality for User Interface (11), Security (12), Users (13), Devices (14) and Application (15) to any Hardware System (40) in the P2P group, thus supporting fully connected, semi-connected or disconnected states.

In one aspect, the Hardware System (40) temporarily mates with the Female Hardware Connection Port In (77) on the Smooth Surface Mount System (70) or the Female Hardware Connection Port In (83) on the Metallic Surface Mount System (80) and onto the Display System (60) through the Hardware System Wiring Interface In (68). If present, the Hardware System (40) is connected, through the Display System (60), Hardware System Wiring Interface Out (67), Female Hardware Connection Port Out (78) on the Smooth Surface Mount System (70) or the Female Hardware Connection Port Out (84) on the Metallic Surface Mount System (80) and temporarily mates with the Display Extension System (50). The Hardware System (40) is physically connected and secured within the Smooth Surface Mount System (70) or alternatively the Hardware Case and Mount System (90) and tangentially connected to the Display System (60). The Hardware System (40) is connected wirelessly to the Cloud Platform (10) or Advertisement Sharing Cloud Platform (20) through a secure connection which is established, monitored and controlled by the Hardware System (40).

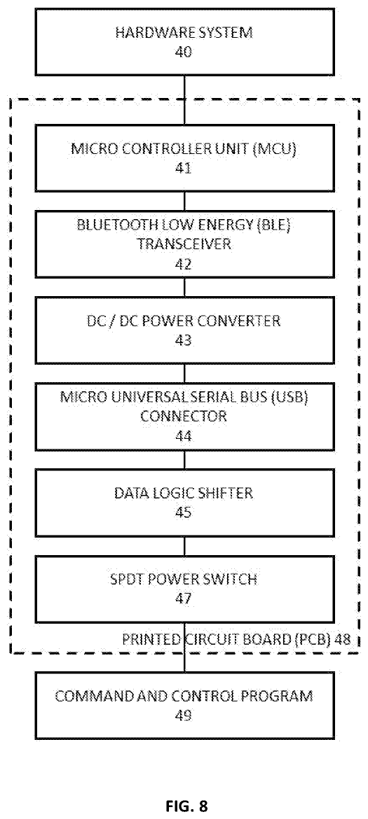

FIG. 8 and FIG. 9 are the block diagrams illustrating two variations of the Hardware System (40) both comprising integrated circuits and components placed on a custom Printed Circuit Board (PCB) (48). The power management components include a standard Micro Universal Serial Bus (USB) Connector (44) the first end connecting directly to a micro Universal Serial Bus (USB) Cable for connection to an external power source and the other end soldered to the Printed Circuit Board (PCB) (48); second is a SPDT Power Switch (47), the first end having a two position ON/OFF slide switch and the second end soldered to the Printed Circuit Board (PCB) (48); third is a DC/DC Power Converter (43), one end of which is soldered to the Printed Circuit Board (PCB) (48); and fourth are multiple Printed Circuit Board (PCB) vias with thermal pads to ground inner layer and multiple Printed Circuit Board (PCB) (48) vias with thermal pads to power inner layer. The two data management components include the Data Logic Shifter (45) one end of which is soldered to the Printed Circuit Board (PCB) (48); and one Printed Circuit Board (PCB) (48) via with no inner layer connection reserved for the Data In connection from the Display System (60). The communications components include the Bluetooth Low Energy (BLE) Transceiver (42) and the IEEE 802.11x (WIFI) Transceiver (46) both onboard the Micro Controller Unit (MCU) (41). The processing, memory and storage components include the Micro Controller Unit (MCU) (41) one end of which is soldered to the Printed Circuit Board (PCB) (48). The core program logic component includes the Command and Control Program (49) that is resident on the Micro Controller Unit (41).

The Hardware System (40) comprises a Flexible or Rigid Printed Circuit Board (PCB) (48) to support end user requirements. In one aspect, the Hardware System (40) comprises multiple Printed Circuit Board (PCB) (48), wherein components are placed on different Printed Circuit Boards (PCB) (48) to support an end user requirement. Optionally or alternatively, the Hardware System (40) may comprise different numbers of and/or sizes of DC/DC Power Converters (43) based on the component's voltage and ampere capacity to support an end user requirement. Optionally or alternatively, the Hardware System (40) may comprise different Micro Controller Units (MCU) (41) to support an end user requirement. Optionally or alternatively, the Hardware System (40) may be configured by changing the size of the Printed Circuit Board (PCB) (48) and the placement of the individual components, including placing components on multiple sides of the Printed Circuit Board (PCB) (48).

### F. Display Extension System

The Display Extension System (50) comprises a set of integrated circuits and components placed on a rigid or flexible printed circuit board (PCB) as well as multiple physical structures custom manufactured of flexible, plastic polymer. The integrated circuits include power management and data management.

The Display Extension System (50) provides a bi-directional data connection between multiple Display Systems (60). The Display Extension System (50) also transmits algorithms, logic and compiled statements to command and control the Display System (60) from the Hardware System (40). The Display Extension System (50) further provides power management and physical connection to extension Display System (60). The Display Extension System (50) also secures, houses and protects the display extension hardware components. The Display Extension System (50) can be used extend the display viewing area by incorporating multiple individual displays. The sixth function of the Display Extension System (50) is to monitor and control the multiple individual displays incorporated into a single overall display viewing area.

In one aspect, the Display Extension System (50) temporarily mates with the Female Hardware Connection Port Out (78) on the Smooth Surface Mount System (70) or the Female Hardware Connection Port Out (84) on the Metallic Surface Mount System (80) and onto the Display System (60) through the Hardware System Wiring Interface Out (67). If two or more Display Systems (60) are present, the Display Extension System (50) temporarily mates with the Female Hardware Connection Port In (77) on the Smooth Surface Mount System (70) or the Female Hardware Connection Port In (83) on the Metallic Surface Mount System (80) and onto the Display System (60) through the Hardware System Wiring Interface In (68). The Display Extension System (50) is physically connected and secured within the Display Extension Hardware Case (57). The Display Extension System (50) is temporarily mated to multiple Display Systems (60).

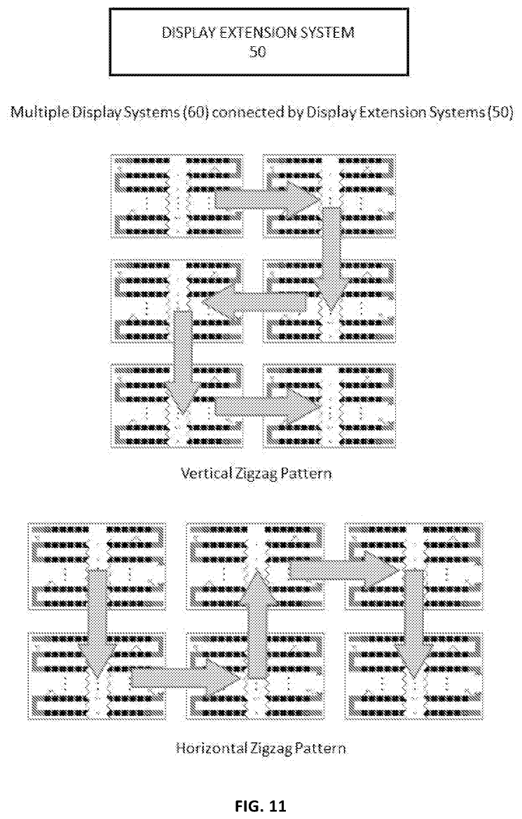

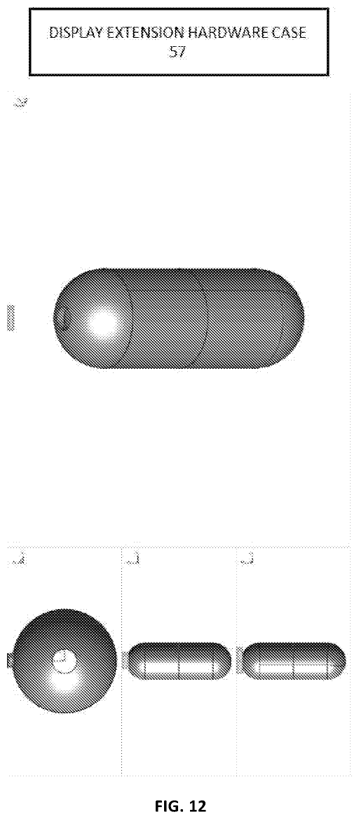

FIG. 10 is a block diagram illustrating physical structures of the Display Extension System (50). One end of the DC/DC Power Converter (51) is soldered to the Printed Circuit Board (55). Both the Connection Cord In (54) and Connection Cord Out (55) are, for example, commercially available SOOW 16/3 AWG 600 voltage portable cord at varying lengths. The three conductors on one end of the Connection Cord In (54) are soldered to their respective positive power, negative power and data connection in vias. The three conductors on other end of the Connection Cord In (54) are secured into their respective positive power, negative power and data connection slot in the Male Display Extension Connection Port In (52). The three conductors on one end of the Connection Cord Out (55) are soldered to their respective positive power, negative power and data connection in vias. The three conductors on other end of the Connection Cord Out (55) are secured into their respective positive power, negative power and data connection slot in the Male Display Extension Connection Port Out (53). The Male Display Extension Connection Port In (52) mates with the Female Display Extension Connection Port Out (78, 84) on the Smooth Surface Mount System (70) and Metallic Surface Mount System (80), respectively. The Male Display Extension Connection Port Out (53) mates with the Female Hardware Connection Port In (77, 83) on the Smooth Surface Mount System (70) and Metallic Surface Mount System (80), respectively. The final component is the Display Extension Hardware Case (57). One side and open end of the top face of the two halves of the Display Extension Hardware Case (57) snaps in place around the Printed Circuit Board (PCB) (56). The two halves of the Display Extension Hardware Case (57) come together to form an internal compartment to accommodate the Printed Circuit Board (PCB) (56) and integrated components. At either end of the Display Extension Hardware Case (57) is a manufactured cutout for Connection Cord In (54) and Connection Cord Out (55). The Display Extension Hardware Case (57) assembled structure is illustrated in FIG. 12. The Connection Cord In (54) and Connection Cord Out (55), commercially available SOOW 16/3 AWG 600 voltage portable cord at varying lengths (not shown), pass through the manufactured cut outs at opposite ends of the Display Extension Hardware Case (57) (shown). FIG. 11 illustrates the Display System (60) tiling options and connections to the Display Extension System (50).

The Display Extension System (50) may comprise Flexible or Rigid Printed Circuit Board (PCB) (56) to support end user requirements. The Display Extension System (50) may comprise different DC/DC Power Converters (51), based on the component's voltage and ampere capacity to support an end user requirement. In one aspect, the Display Extension System (50) comprises multiple DC/DC Power Converters (51) based on the component's voltage and ampere capacity to support an end user requirement. The fourth structural variation of the Display Extension System (50) is to change the size of the Printed Circuit Board (PCB) (56) and the placement of the individual components, including placing components on multiple sides of the Printed Circuit Board (PCB) (56). The various implementations, of the Display Extension System (50), the Connection Cord In (54) and Connection Cord Out (55) can vary in length based on end user requirements. The overall dimension of the Display Extension Hardware Case (57) can vary based on end user requirements.

### G. Display System

The Display System (60) comprises a predetermined number of Addressable Light Emitted Diodes (LED) (61) arranged in a series of rows and columns of a certain spacing and connected by a Conductive Medium (62) in a zigzag column/row pattern such that the individual LED connection pads create three continuous conductive positive power, negative power and data connections. The completed array is encapsulated in a substrate for protection and durability, and mates with the Hardware System (40) at the connection points at the beginning of the series, and in some cases mates with the Display Extension Systems (50) at the connection points at the beginning and/or ends or the series. The Display System (60) is assembled in a Smooth Surface Mount System (70) or Metallic Surface Mount System (80) for repeated temporary adhesion to a smooth or metallic surface.

The Display System (60) displays text, graphic or animation content and executes commands or controls provided from the Hardware System (40). The Display System (60) also provides display status and confirmation of displayed content back to the Hardware System (40). The Display System (60) provides scalability of the display viewing area, such that it can be placed with a series of other Display Systems (60) to function as a single display unit. The Display System (60) provides flexibility in the number and placement of the individual LEDs, such that the overall dimensions, density and proportions can be controlled to yield various sizes, shapes and LED counts for completed Display Systems (60). The Display System (60) also provides flexibility in how and what material(s), e.g. polymers, plastics, resins, are used during the manufacturing process to encapsulate the Display Array (63), such that the properties, dimensions, characteristics and appearance can be controlled to yield various sizes, colors and specifications for completed Display Systems (60).

The Display System (60) is indirectly and temporarily mated to the Hardware System (40) through a positive power, negative power and data in connection ports. In some cases, the Display System (60) is indirectly and temporarily mated to one or more the Display Extension Systems (50) through a positive power, negative power and data in and/or out connection ports. The Display System (60) is hardwired directly to Female Hardware Connection Port In (77) and Display Extension Connection Port Out (78) through the Hardware System Wiring Interface In and Out (67, 68), respectively; assembled and secured within the Smooth Surface Mount System (70). Alternatively, the Display System (60) is hardwired directly to Female Hardware Connection Port In (83) and Display Extension Connection Port Out (84) through the Hardware System Wiring Interface In and Out (67, 68), respectively; assembled and secured within the Metallic Surface Mount System (80). The Display System (60) has a bidirectional communication and tangential wireless connection to the Cloud Platform (10) or Advertisement Sharing Cloud Platform (20) through a secure connection.

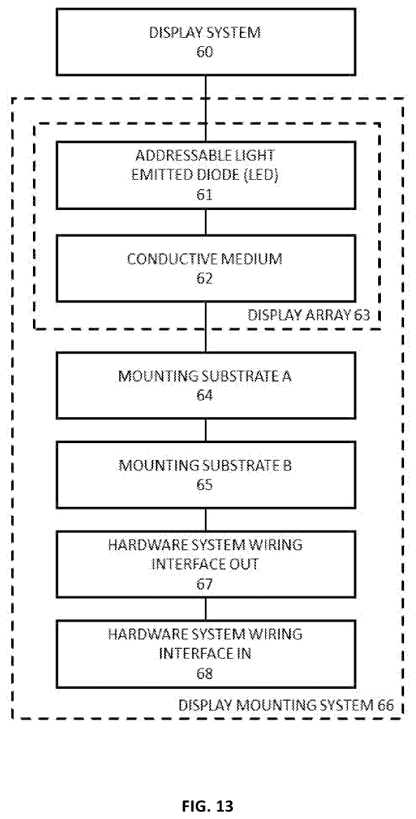

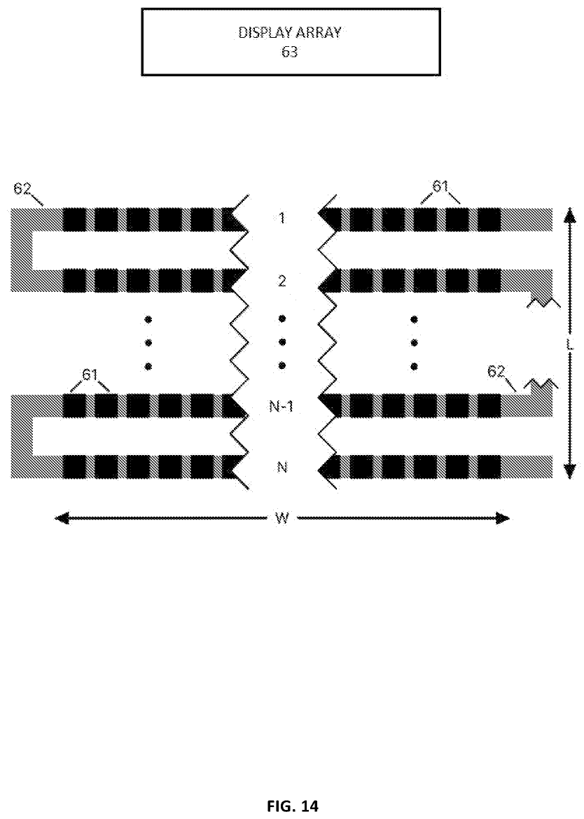

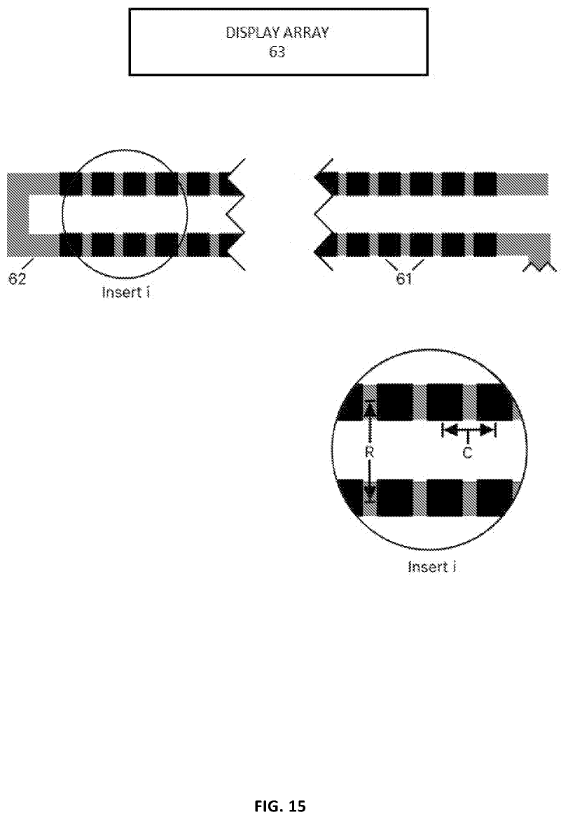

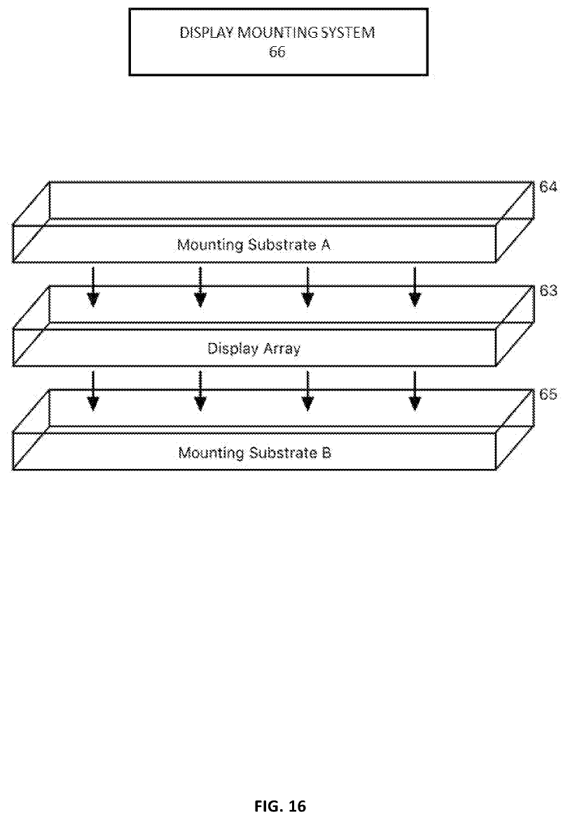

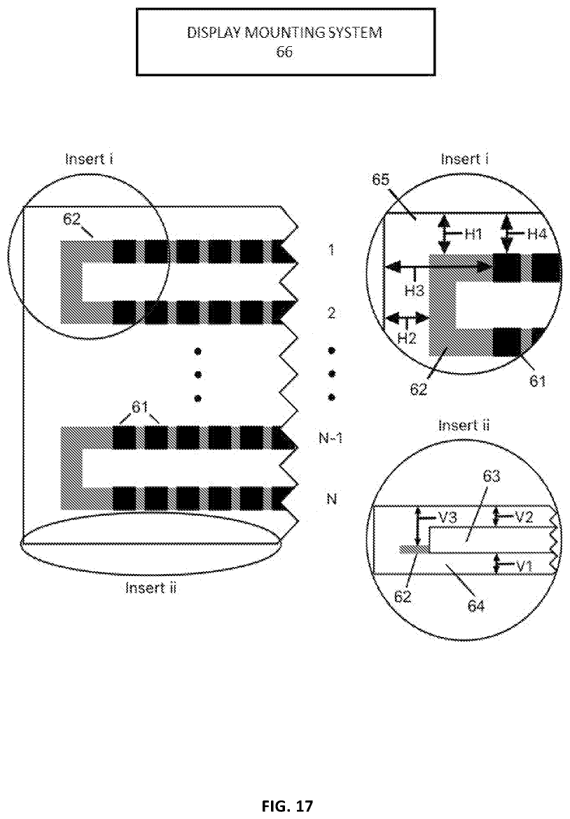

FIG. 13 is the block diagram illustrating the Display System (60). A predetermined number of addressable Light Emitted Diodes (LED) (61) are arranged into a predetermined number a of rows and columns. The distance between the LEDs, depicted in FIG. 14 as variable ‘r’ and variable ‘c’, can vary based on end user requirements. The overall dimensions of the Display Array (63), depicted in FIG. 15 as variable ‘L’ and variable ‘W’ can also vary based on end user requirements. Once placement of the LEDs is determined, the bottom side of the Addressable Light Emitted Diodes (LED) (61) are permanently soldered to the Conductive Medium (62) as illustrated in FIG. 14 and FIG. 15 and repeated for all LEDs. This combination of materials produces the Display Array (63). In the manufacturing process, the Display Array (63) may be positioned between two substrates, Mounting Substrate A (64) and Mounting Substrate B (65) and permanently joined together as illustrated in FIG. 16. The type of materials used for Mounting Substrate A (64) and Mounting Substrate B (65) during the manufacturing process can vary in property, characteristic and appearance depending on end user requirements. Furthermore, Mounting Substrates A and B (64, 65) do not have to be of the same or similar material, but do have to exceed predefined permanent adhesion thresholds with each other and with the Display Array (63). The horizontal border and vertical border surrounding the Display Array (63), depicted in FIG. 17 as variables ‘H1’, ‘H2’, ‘H3’, H4’, ‘V1’, ‘V2’, ‘V3’ can vary based on end user requirements. The Hardware System Wiring Interface Out (67) provides the positive power out, negative power out and data out connections to be hardwired to the Female Hardware Connection Port In (77, 83) on the appropriate surface mounting system during the downstream mounting process. Hardware System Wiring Interface In (68) provides the positive power in, negative power in and data in connections to be hardwired to the Female Hardware Connection Port Out (78, 84) on the appropriate surface mounting system during the downstream mounting process.

A structural variation of the Display System (60) is the ability to provide flexibility in the number and placement of the individual LEDs, such that the overall dimensions, density and proportions can be controlled to yield various sizes, shapes and LED counts for completed Display Systems (60). Another structural variation of the Display System (60) is the ability to provide flexibility in how and what material(s), e.g. polymers, plastics, resins, are used during the manufacturing process to encapsulate the Display Array (63), such that the properties, dimensions, characteristics and appearance can be controlled to yield various sizes, colors and specifications for completed Display Systems (60). A functional variation of the Display System (60) is the ability to scale the display viewing area, such that it can be placed with a series of other Display Systems (60) to function as a single display unit.

### H. Smooth Surface Mount System

The Smooth Surface Mount System (70) comprises multiple physical structures manufactured of flexible, plastic polymer. Each part comprises two halves and each half has a mounting receptacle incorporated into one side to facilitate temporary mounting to various external smooth surfaces. The opposite side of the part half has slotted surfaces on which to lock into the mating part half and to secure the Display System (60) between the two halves.

A function of the Smooth Surface Mount System (70) is to secure the Display System (60) in place. Another function of the Smooth Surface Mount System (70) is to secure and protect the Hardware System (40). Yet another function of the Smooth Surface Mount System (70) is to enable temporary mounting on an external, smooth surface. Another function of the Smooth Surface Mount System (70) is to secure and position the Hardware System Wiring Interfaces (68, 69) on the Display System (60) with their respective Connection Ports (77, 78) on the Smooth Surface Mount System (70). And yet another function of the Smooth Surface Mount System (70) is to cover the internal components and wiring to provide a presentation-quality, professional finished look.

The Smooth Surface Mount System (70) is temporarily mated to the Hardware System (40) and in some cases temporarily mated to the Display Extension System (50). The Smooth Surface Mount System (70) is hardwired directly through Female Hardware Connection Port In (77) and Display Extension Connection Port Out (78) to the Hardware System Wiring Interface In and Out (67, 68), respectively; and assembled around the Display System (60). The Smooth Surface Mount System (70) is temporarily adhered to any smooth surface, e.g. glass, ceramic, plastic.

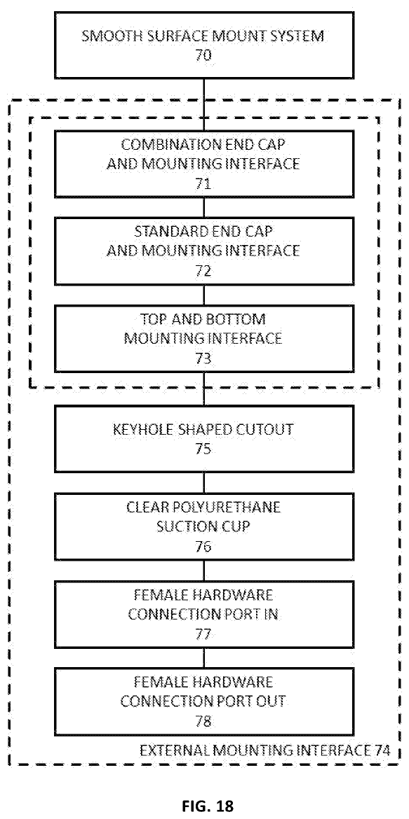

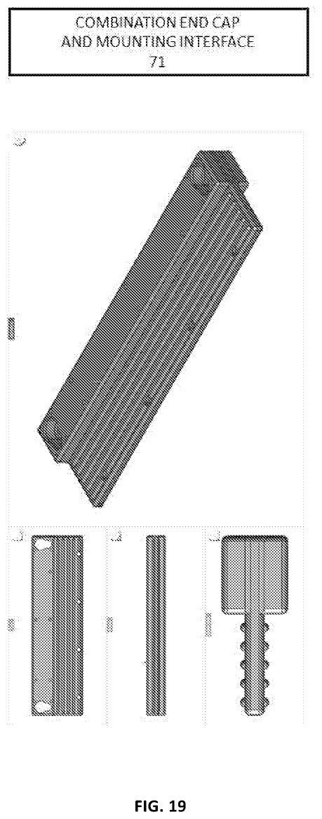

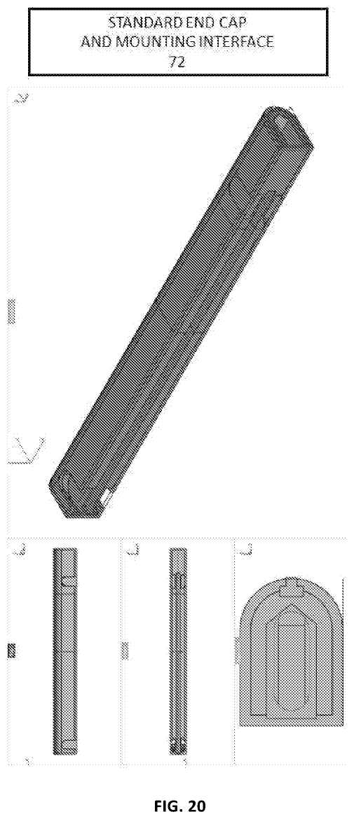

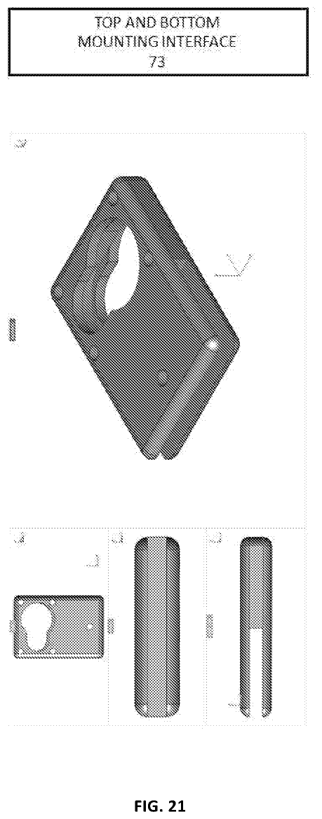

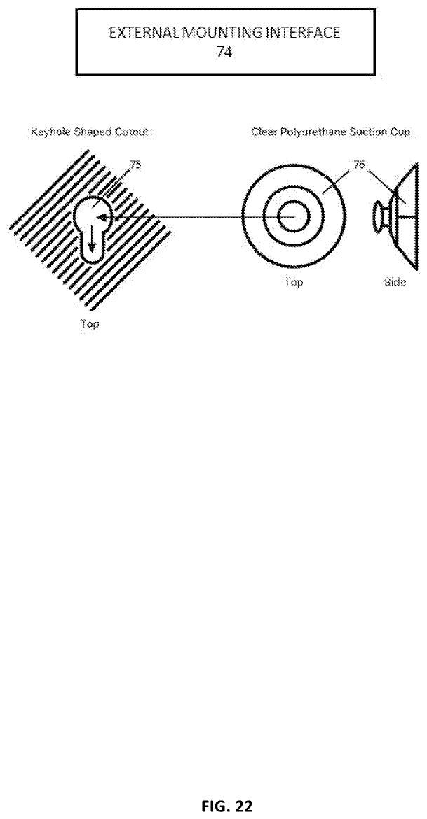

FIG. 18 is a block diagram illustrating the physical structures of the Smooth Surface Mount System (70). The first component is the Combination End Cap and Mounting Interface (71). Opposite ends of one side of the top face of the Combination End Cap and Mounting Interface (71) have two Keyhole-Shaped Cutouts (75) in which to attach a commercially available Clear Polyurethane Suction Cup (76) as illustrated in FIG. 22. The second side and open end of the top face of the two halves of the Combination End Cap and Mounting Interface (71) snaps in place around one end of the Display System (60). The two halves of the Combination End Cap and Mounting Interface (71) come together to form an internal compartment to accommodate the Hardware System (40). At one end of the Combination End Cap and Mounting Interface (71) is a manufactured slot for the commercially available Female Hardware Connection Port In (77) positioned at the upper, left side of the Display System (60). One end of the commercially available Female Hardware Connection Port In (77) is connected to the Hardware System Wiring Interface In (68). One end of the Combination End Cap and Mounting Interface (71) provides manufactured cutout ports for the Micro Universal Serial Bus (USB) connector (44) and SPDT Power Switch (49). The Combination End Cap and Mounting Interface (71) assembled structure is illustrated in FIG. 19. The second component is the Standard End Cap and Mounting Interface (72). Opposite ends of one side of the top face of the Standard End Cap and Mounting Interface (72) have two Keyhole-Shaped Cutouts (75) in which to attach a commercially available Clear Polyurethane Suction Cup (76) as illustrated in FIG. 22. The second side and open end of the top face of the two halves of the Standard End Cap and Mounting Interface (72) snap in place around the other end of the Display System (60). At one end of the Standard End Cap and Mounting Interface (72) is a manufactured slot for the commercially available Female Hardware Connection Port In (77) positioned at the upper, left side of the display and the commercially available Female Hardware Connection Port Out (78) positioned at the bottom, right side of the display. One end of the Female Hardware Connection Port In (77) is connected to the Hardware System Wiring Interface In (68). One end of the Female Hardware Connection Port Out (78) is connected to the Hardware System Wiring Interface Out (67). The Standard End Cap and Mounting Interface (72) assembled structure is illustrated in FIG. 20. The third component is the Top and Bottom Mounting Interface (73). The top face of the Top and Bottom Mounting Interface (73) has one Keyhole-Shaped Cutouts (65) in which to attach a commercially available Clear Polyurethane Suction Cup (66) as illustrated in FIG. 22. The open end of the two halves of the Top and Bottom Mounting Interface (73) snap in place around specific points along the top and bottom edge of the Display System (60). The Top and Bottom Mounting Interface (73) assembled structure is illustrated in FIG. 21. Multiple Top and Bottom Mounting Interface (73) structures can be added to distribute and support the weight of the Display System (60).

A first structural variation of the Smooth Surface Mount System (70) is separating the Combination End Cap and Mount Interface (71) into two physical structures; the Hardware Case and Mount System (90) combined with a Standard End Cap and Mounting Interface (72). A second structural variation of the Smooth Surface Mount System (70) is to change the External Mounting Interface (74) and Clear Polyurethane Suction Cup (76) and utilize an alternative temporary or permanent mounting interface such as screws, bolts or adhesives.

### I. Metallic Surface Mount System

The Metallic Surface Mount System (80) comprises multiple physical structures. The first custom manufactured, polymer plastic part comprises of two halves. Each half has a slotted surface on one side on which to lock into the mating part half. The Display System (60) is positioned and secured between the two halves. A compartment is formed for the Hardware System (40) between the two halves. The second part is manufactured of flexible, polymer capable of temporary magnetic adhesion. The front face of the polymer is permanently adhered to the Display System (60) during the manufacturing process. The back face of the polymer is used to temporarily mount to a metallic surface.

One function of the Metallic Surface Mount System (80) is to secure the Display System (60) in place. Another function of the Metallic Surface Mount System (80) is to secure and protect the Hardware System (40). A third function of the Metallic Surface Mount System (80) is to enable temporary mounting on an external, metallic surface. A fourth function of the Metallic Surface Mount System (80) is to secure and position the Wiring Interfaces (68, 69) on the Display System (60) with their respective Connection Ports (83, 84) on the Metallic Surface Mount System (80). A fifth function of the Metallic Surface Mount System (80) is to cover the internal components and wiring to provide a presentation-quality, professional finished look.

The Metallic Surface Mount System (80) is temporarily mated to the Hardware System (40) and in some cases temporarily mated to the Display Extension System (50). The Metallic Surface Mount System (80) is hardwired directly through Female Hardware Connection Port In (83) and Display Extension Connection Port Out (84) to the Hardware System Wiring Interface In and Out (67, 68), respectively; and assembled around the Display System (60). The Metallic Surface Mount System (80) is temporarily adhered to any metallic surface, e.g. metal, metal-finished/coated, fused metal.

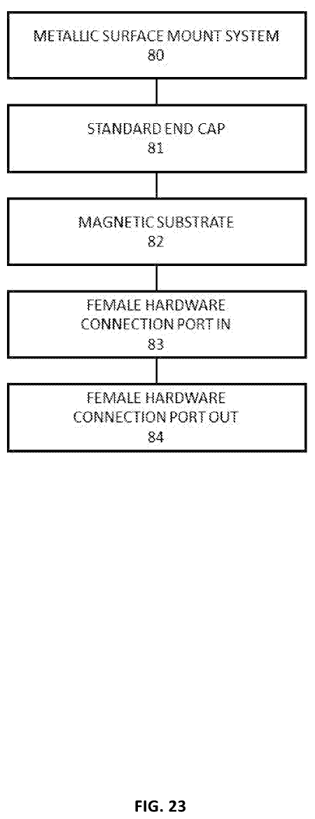

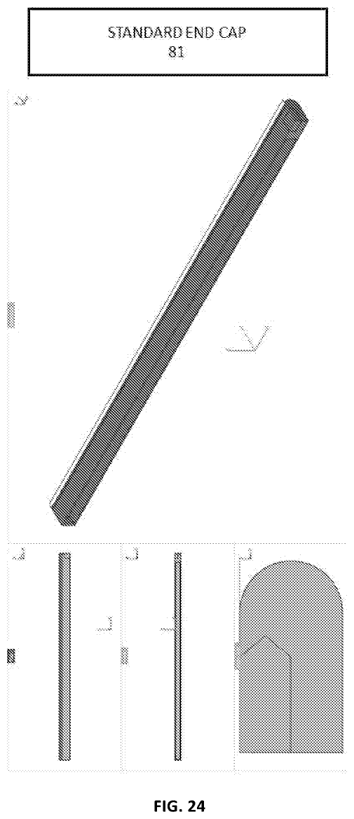

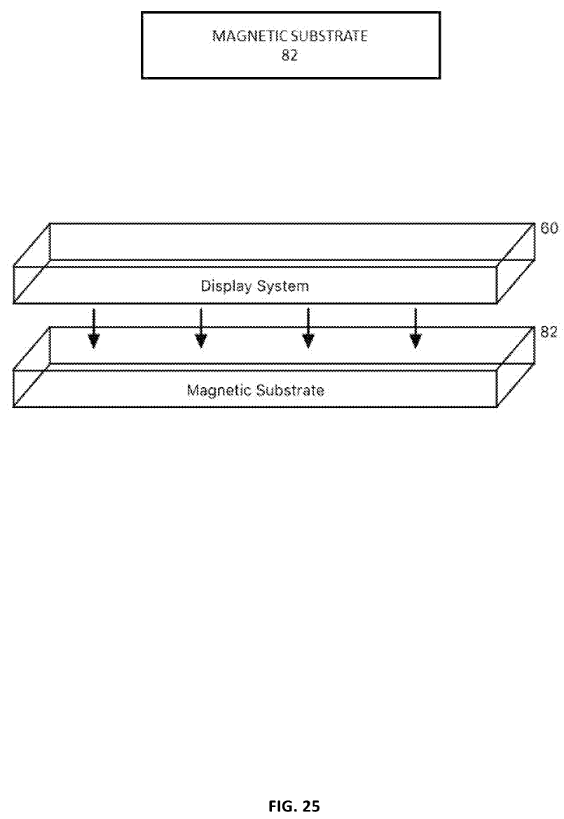

FIG. 23 is a block diagram illustrating the components of the Metallic Surface Mount System (80). The first component is the Standard End Cap (81). The first side and open end of the top face of the two halves of the Standard End Cap (81) snap in place around the end of the Display System (60) and Magnetic Substrate (82). At one end of the Standard End Cap (81) is a manufactured slot for the commercially available Female Hardware Connection Port In (83) positioned at the upper, left side of the display and the commercially available Female Hardware Connection Port Out (84) positioned at the bottom, right side of the display. One end of the Female Hardware Connection Port In (83) is connected to the Hardware System Wiring Interface In (68). One end of the Female Hardware Connection Port Out (84) is connected to the Hardware System Wiring Interface Out (67). The Standard End Cap (81) assembled structure is illustrated in FIG. 24. The second component is the Magnetic Substrate (82). The top face of the Magnetic Substrate (82) provides a surface on which to permanently adhered to the Display System (60). During the manufacturing process the bottom face of the Display System (60) is positioned on the top face of the Magnetic Substrate (82) and permanent bonded together as illustrated in FIG. 25.

A first structural variation of the Metallic Surface Mount System (80) is the dimensions of the Mounting Substrate (82) and is directly proportionate to the total number of LED columns and rows, and the horizontal and vertical spacing between individual LEDs, e.g. the overall size of the Display System (60). A second structural variation of the Metallic Surface Mount System (80) is the process in which the Display System (60) is adhered to the Magnetic Substrate (82) and in some embodiments, may include additional polymer or plastic substrates or commercial bonding agents to secure and bond the two surfaces.

### J. Hardware Case and Mount System

The Hardware Case and Mount System (90) comprises multiple physical structures custom manufactured of flexible, plastic polymer and commercially available components.

A first function of the Hardware Case and Mount System (90) is to secure and protect the Hardware System (40). A second function of the Hardware Case and Mount System (90) is to provide a connection between the Hardware System (40) and the Display System (60). A third function of the Hardware Case and Mount System (90) is to cover the internal Hardware System (40) components and wiring to provide a presentation-quality, professional finished look.

The Male Hardware Connection Port Out (93) on the Hardware Case and Mount System (90) temporarily mates with the Female Hardware Connection Port In (77) on the Smooth Surface Mount System (70) or the Female Hardware Connection Port In (83) on the Metallic Surface Mount System (80) and onto the Display System (60) through the Hardware System Wiring Interface In (68). If present, the Male Hardware Connection Port Out (93) on the Hardware Case and Mount System (90) is connected, through the Display System (60), Hardware System Wiring Interface Out (67), Female Hardware Connection Port Out (78) on the Smooth Surface Mount System (70) or the Female Hardware Connection Port Out (84) on the Metallic Surface Mount System (80) and tangentially mates with the Display Extension System (50). The Hardware Case and Mount System (90) houses and secures the Hardware System (40).

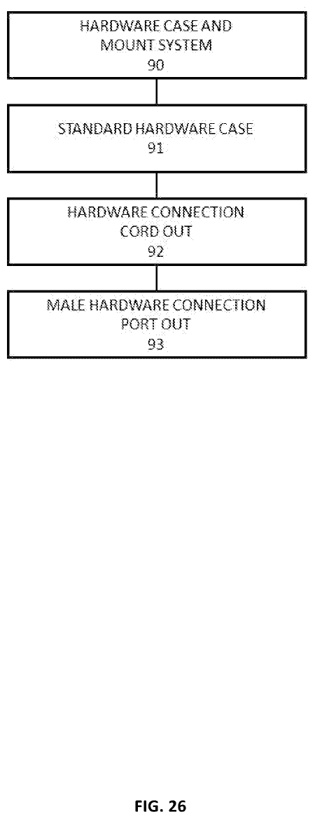

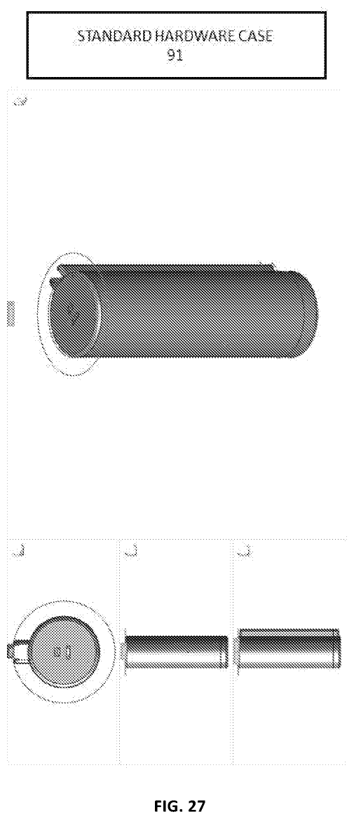

FIG. 26 is the block diagram illustrating components of the Hardware Case and Mount System (90). The first component is the Standard Hardware Case (91). The open face of the two halves of the cylindrical Standard Hardware Case (91) snap in place around the Hardware System (40). The first end of the Standard Hardware Case (91) provides manufactured cutout ports for the Micro Universal Serial Bus (USB) connector (44) and SPDT Power Switch (49). The opposite end of the Standard Hardware Case (91) provides a manufactured cutout for the Hardware Connection Cord Out (92). The Hardware Connection Cord Out (92) comprises of a commercially available SOOW 16/3 AWG 600 voltage portable cord of varying length. The three conductors on one end of the Hardware Connection Cord Out (92) are soldered to their respective Positive power, negative power and data connection in vias on the Printed Circuit Board (47) of the Hardware System (40). The three conductors on other end of the Hardware Connection Cord Out (92) are secured into their respective positive power, negative power and data connection slots in the commercially available Male Hardware Connection Port Out (93). The Male Hardware Connection Port Out (93) mates with their respective Female Hardware Connection Port In (77, 83) on the Smooth Surface Mount System (70) or Metallic Surface Mount System (80). FIG. 27 illustrates the assembled structure of the Standard End Cap (91).

A structural variation of the Hardware Case and Mount System (90) is that the length of the Hardware Connection Cord Out (92) can vary in length based on end user requirements. Another structural variation of the Hardware Case and Mount System (90) is the overall size and shape of the Standard Hardware Case (91) can vary based on end user requirements.

### K. Connections of Main Elements and Sub-Elements of Invention

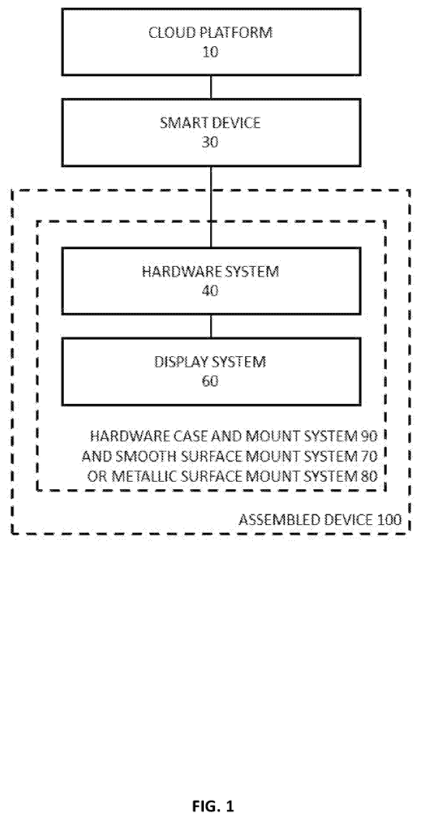

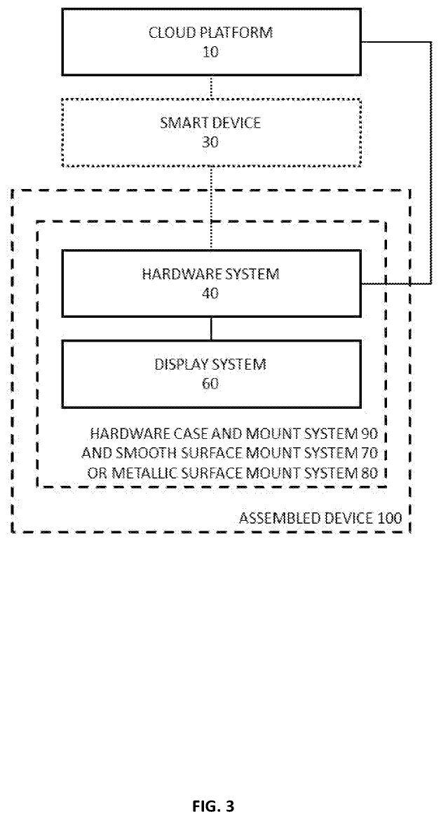

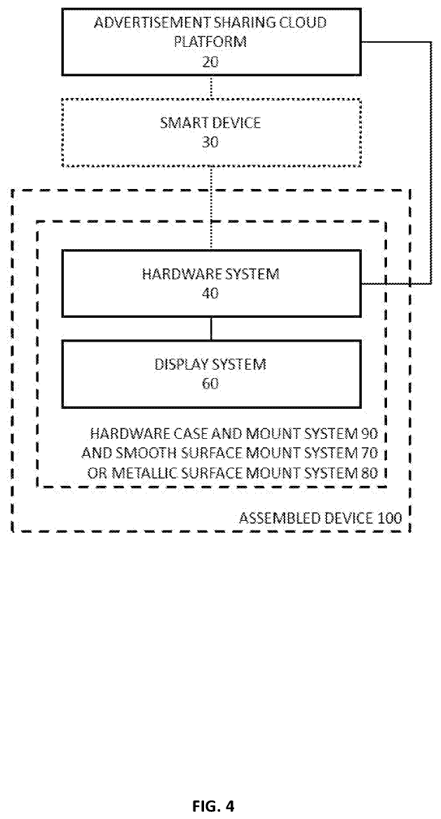

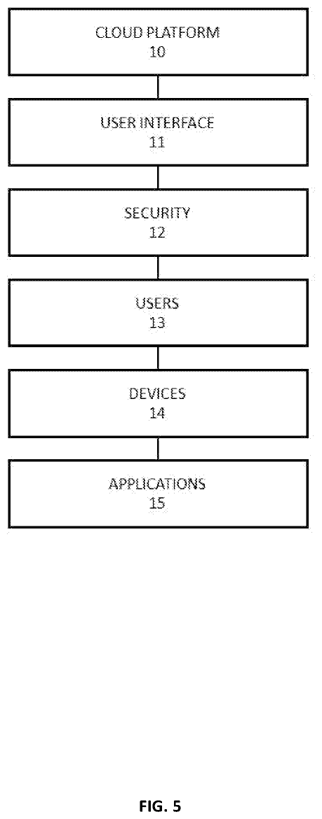

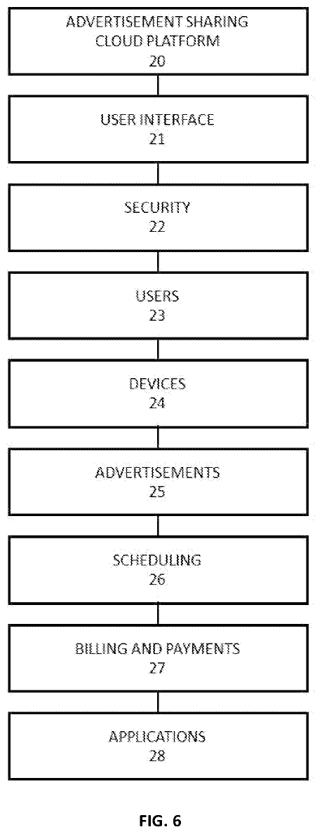

The Cloud Platform (10) or Advertisement Sharing Cloud Platform (20) have an electronic, non-persistent connection to the Smart Device (30) utilizing the onboard Cellular Transceiver (33) or IEEE 802.11x (WIFI) Transceiver (34) as illustrated in FIG. 1, FIG. 2 and FIG. 7; or as FIG. 3, FIG. 4 and FIG. 9 illustrate the Cloud Platform (10) or Advertisement Sharing Cloud Platform (20) can have an electronic, non-persistent connection directly to the Hardware System (40) utilizing the IEEE 802.11x (WIFI) Transceiver (46). FIG. 1 and FIG. 2 show how the Smart Device (30) utilizes the onboard Bluetooth Low Energy (BLE) Transceiver (32) illustrated in FIG. 7 to establish and maintain a persistent electronic connection to the Hardware System (40) utilizing the onboard Bluetooth Low Energy (BLE) Transceiver (42) illustrated in FIG. 8 and FIG. 9. The Display System (60) illustrated in FIG. 13 is comprised of a variable width and length matrices of Addressable Light Emitted Diodes (LED) (61) connected via Conductive Medium (62) that together form a Display Array (63) as illustrated in FIG. 14 and FIG. 15. The Display Array (63) is sandwiched between two substrates, Mounting Substrate A (64) and Mounting Substrate B (65) to a specific width, length and depth to form a Display Mounting System (66) as illustrated in FIG. 16 and FIG. 17. The Display System (60) onboard Hardware System Wiring Interface In (68) is connected to the Female Hardware Connection Port In (77) or Female Hardware Connection Port In (83) and the Hardware System Wiring Interface Out (67) is connected to the Female Display Extension Connection Port Out (78) or Female Display Extension Connection Port Out (84) on the Smooth Surface Mount System (70) illustrated in FIG. 18 or Metallic Surface Mount System (80) illustrated in FIG. 23. The Female Hardware Connection Port In (77, 83) mate with the Male Hardware Connection Port Out (93) which is connected to the Hardware Connection Cord Out (92) on the Hardware Case and Mount System (90) illustrated in FIG. 26. The opposite end of which is hardwired to the Printed Circuit Board (PCB) (48) and through the Hardware System (40) onboard DC/DC Power Converter (43) for power management and Data Logic Shifter (45) for data management and is controlled through the Command and Control Program (49) preloaded onto the Micro Controller Unit (MCU) (41) as illustrated in FIG. 8 and FIG. 9. The Hardware System Wiring Interface Out (67) on the Display System (60) is connected to the Female Display Extension Connection Port Out (78) or the Female Display Extension Connection Port Out (84) illustrated in FIG. 13, FIG. 18 and FIG. 23. In certain cases where one or more Display Extension Systems (50) are utilized, the Female Display Extension Connection Port Out (78, 84) are mated to the Male Display Extension Connection Port In (52) which is connected to one end of the Connection Cord In (54). The other end of the Connection Cord In (54) is hardwired to the Display Extension System (50) Printed Circuit Board (PCB) (56) which passes through the soldered connection on one end of the Connection Cord Out (55) and to the other end of the Connection Cord Out (55) to the Male Display Extension Connection Port Out (53). This is mated to either the Female Hardware Connection Port In (77) or the Female Hardware Connection Port In (83) and then to the next physical Display System (60) as illustrated in FIG. 10, FIG. 13, FIG. 18 and FIG. 23. As illustrated in FIG. 18, the Smooth Surface Mount System (70) comprises of one or multiple physical structures used to house and secure the Hardware System (40) and Display System (60), and provide an interface, support and system to temporarily mount the structure onto various smooth surfaces with connections. This embodiment of the system is illustrated in FIG. 19, FIG. 20, FIG. 21 and FIG. 22 and comprises of three different physical structures, each constructed of a rigid or semi-rigid plastic polymer; each having one or more Keyhole-Shaped Cutouts (75) in which to attach a commercially available Clear Polyurethane Suction Cup (76); and are constructed of two halves that snap together in position around the Display System (60) and Hardware System (40). Multiple Top and Bottom Mounting Interface (73) structures, FIG. 21, can be added to distribute and support the weight of the Display System (60). The Standard End Cap and Mounting Interface (72) in FIG. 20 supports the Display Device (60) and the Combination End Cap and Mounting Interface (71) in FIG. 19 also contains a compartment to accommodate the Hardware System (40) and provides ports for the Micro Universal Serial Bus (USB) connector (44) and SPDT Power Switch (47). A Metallic Surface Mount System (80) illustrated in FIG. 23, FIG. 24 and FIG. 25 secures the Display System (60) with a mounting system capable of temporarily mounting to a metallic surface and is used in conjunction with the Hardware Case and Mount System (90) illustrated in FIG. 26 and FIG. 27. The Assembled Device (100) comprises of multiple physical structures and sub-assemblies used to embody the Hardware System (40), Display System (60), Hardware Case and Mount System (90), Smooth Surface Mount System (70) or in certain embodiments the Metallic Surface Mount System (80) as illustrated in FIG. 1, FIG. 2, FIG. 3 or FIG. 4. FIG. 5 illustrates how users access the Applications (15) on the Cloud Platform (10) facilitated through the User Interface (11) and access controlled by the Security (12); and alternatively, users access the Applications (28) on the Advertisement Sharing Cloud Platform (20) through the User Interface (21) and access controlled by the Security (22) as illustrated in FIG. 6. Users interact and control the Display System (60) by interacting with the Mobile Application (35) on the Smart Device (30); or users interact and control the Display System (60) by interacting with the Applications (15) on the Cloud Platform (10) or Applications (28) on the Advertisement Sharing Cloud Platform (20) illustrated in FIG. 5 and FIG. 6.

Alternatively, the Cloud Platform (10) can incorporate advertisement sharing components as in the Advertisement Sharing Cloud Platform (20). Alternatively, users can interact and control the Display System (60) using the Applications (15) on the Cloud Platform (10). Alternatively, users can interact and control the Display System (60) using the Applications (28) on the Advertisement Sharing Cloud Platform (20). Alternatively, the Hardware System (40) can communicate with the Cloud Platform (10) using the IEEE 8021.11x (WIFI) Transceiver (46). Alternatively, the Hardware System (40) can communicate with the Advertisement Sharing Cloud Platform (20) using the IEEE 8021.11x (WIFI) Transceiver (46). Alternatively, the Smart Device (30) can communicate with the Cloud Platform (10) using the IEEE 802.11x (WIFI) transceiver (34). Alternatively, the Smart Device (30) can communicate with the Advertisement Sharing Cloud Platform (20) using the IEEE 802.11x (WIFI) transceiver (34). Alternatively, the DC/DC Power Converter (43) on the Hardware System (40) can vary in size and form factor to accommodate higher voltage/power requirements. Alternatively, the Printed Circuit Board (PCB) (48) on the Hardware System (40) can vary in size and form factor to accommodate different integrated circuits (ICs). Alternatively, the Printed Circuit Board (PCB) (48) on the Hardware System (40) can be manufactured in a flexible PCB material. Alternatively, the number of Addressable Light Emitted Diode (LED) (61) can vary by length (L) and width (W) and overall size and count of LEDs included in the Display Array (63) as illustrated in FIG. 14. Alternatively, the spacing of Addressable Light Emitted Diode (LED) (61) can vary by row (r) and column (c) and overall size of the Display Array (63) as depicted in FIG. 15. Alternatively, the material and physical properties of the Mounting Substrate A (64) and Mounting Substrate B (65) can vary depending on application requirements for example clear polyurethane or 100% opaque polyvinyl chloride (PVC). Alternatively, the border of the Display Mounting System (66) can vary by H1, H2, H3, H4 and V1, V2, V3 as depicted in FIG. 17. Alternatively, the number of Top and Bottom Mounting Interface (73) included during assembly can vary based on application requirements and overall size and weight of the Display System (60). Alternatively, the commercially available Clear Polyurethane Suction Cup (76) can be replaced by with a 1″, 2″ or 3″ commercially available Suction Cup depending on application requirements. Alternatively, one or more Display Extension Systems (50) can be used to increase the number of Display Systems (60) and the overall display area. Alternatively, the Hardware Case and Mount System (90) can be used in conjunction with components in the Smooth Surface Mount System (70) to mount the Hardware System (50) and Display System (60) in separate cases. Alternatively, the Display Array (63) could be mounted on different substrates, e.g. vinyl, plastic, PVC and hung, or temporarily or permanently adhered to a surface and in some cases eliminating the need for some or all the surface mounting components. Alternatively, the Light Emitted Diodes (61) and Conductive Medium (62) could be mounted directly to different substrates, e.g. vinyl, plastic, PVC and hung, or temporarily or permanently adhered to a surface and in some cases eliminating the need for some or all the surface mounting components.

### L. Operation

Upon power on of the Assembled Device (100), the user utilizes any standard Internet browser (e. G. Explorer, Chrome, Foxfire) to gain access to the Cloud Platform (10) through the User Interface (11) and follows the process flow outlined in FIG. 38 to register the Assembled Device (100). At the time of device registration, a unique device certification number is generated and securely logged on the Cloud Platform (10). User specific information is populated in Users (13) and Devices (14).

Alternatively, the user can utilize any standard Internet browser (e. G. Explorer, Chrome, Foxfire) to gain access to the Advertisement Sharing Cloud Platform (20) through the User Interface (21) and follow the process flow outlined in FIG. 38 to register the Assembled Device (100). At the time of device registration, a unique device certification number is generated and securely logged on the Advertisement Sharing Cloud Platform (20).

Based on the device information provided by the user, the Cloud Platform (10) or Advertisement Sharing Cloud Platform (20) automatically configures the size of the Display System (60) using the unique Dynamic Grid Map Sizing algorithm and automatically configure the individual matrices position parameters using the unique Dynamic Position/Color Map algorithm in the process flow outlined in FIG. 28 and update the Devices (14) or Devices (24). User specific information is populated in Users (23) and Devices (24).

If required, multiple Display Systems (60) can be temporarily linked together using one or more Display Extension Systems (50). Users temporarily mount, forward-facing or reverse-facing, the Assembled Device (100), and if present additional Display Extension System (50) connected Display Systems (60), onto any smooth surface by inserting the Clear Polyurethane Suction Cups (66) into the appropriate Keyhole Shaped Cutout (65) on all the External Mounting Interfaces (64) and attaching to the surface. Alternatively, the user can forward-face mount the Assembled Device (100), and if present additional Display Extension System (50) connected Display Systems (60), onto any metallic surface through contact with the Magnetic Substrate (82) and the metallic surface.

Users download the Mobile Application (35) on their Smart Device (30) from the Apple App Store, Microsoft Mobile Store or Android Store. The Mobile Application (35) automatically connects to the Cloud Platform (10) or Advertisement Sharing Cloud Platform (20) utilizing the IEEE 802.11x (WIFI) Transceiver (34) or Cellular Transceiver (33). Alternatively, the user can connect directly to the Cloud Platform (10) or Advertisement Sharing Cloud Platform (20) from the Hardware System (50) using the, if present, onboard IEEE 802.11x (WIFI) Transceiver (46) to access the Applications (15) on the Cloud Platform (10) or Applications (28) on the Advertisement Sharing Cloud Platform (20), referred to as “Direct to Cloud” or “IoT” connection method.

If the user has successfully completed Assembled Device (100) registration, the information automatically populates the cloud or mobile application. If not, the user is prompted to register the Assembled Device (100) as outlined in the process flow highlighted in FIG. 37. The cloud or mobile application synchronizes registration information with the Users (13) and Devices (14) on the Cloud Platform (10). Alternatively, the cloud or mobile application synchronizes registration information with the Users (23) and Devices (24) on the Advertisement Sharing Cloud Platform (20).

The user powers on the Assembled Device (100), and if present additional Display Extension System (50) connected Display Systems (60), by connecting one end of the power cable into a wall outlet, car outlet or computer USB power port and the other end of the cable into the Micro Universal Serial Bus (UBS) Connector (44) of the Hardware System (40). If connecting using the Smart Device (30) method, the Assembled Device (100) searches for available Bluetooth devices using the onboard Bluetooth Low Energy (BLE) Transceiver (42). The user launches the Mobile Application (35), searches and pairs their Smart Device (30) with the Assembled Device (100) in the list. Alternatively, if connecting using the “Direct to Cloud” or “IoT” connection method, the Assembled Device (100) searches for available WIFI connections using the onboard IEEE 802.11x (WIFI) Transceiver (46) and launches the cloud application.

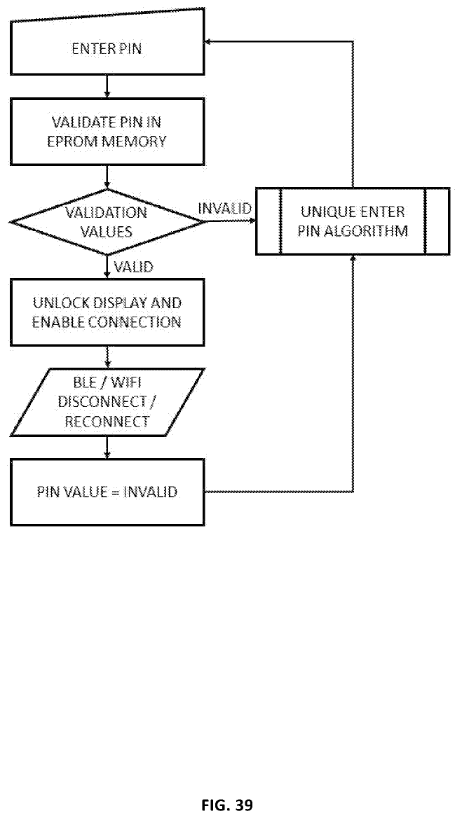

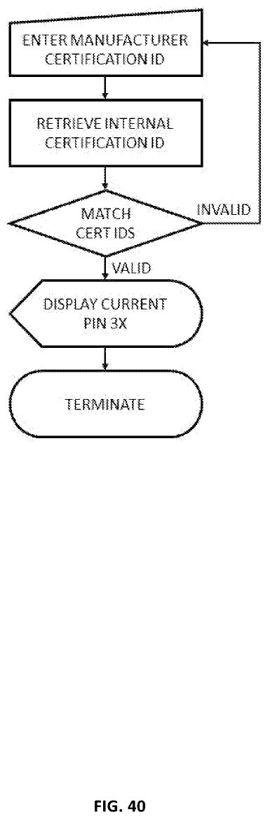

The user establishes a PIN to restrict unauthorized access and secure the device by following the process flow outlined in FIG. 38. The BLE connection between the Smart Device (30) and Assembled Device (100) is a mandatory, persistent connection. If connection is lost, the user is prompted to enter the PIN to access the Assembled Device (100) as outlined in the process flow outlined in FIG. 39 and governed by the unique Enter PIN algorithm. If the user forgets or loses their PIN, they can retrieve it by entering the manufacturer Certification ID as outlined in the process flow in FIG. 40. Alternatively, users can configure the IEEE 802.11x (WIFI) Transceiver (46) in the Hardware System (40) to automatically connect to the Cloud Platform (10) or Advertisement Sharing Cloud Platform (20) enabling the user to access the Assembled Device (100) through the Applications (15) on the Cloud Platform (10) or the Applications (28) on the Advertisement Sharing Cloud Platform (20) in addition to the Mobile Application (35) on the Smart Device (30). The same PIN restrictions and access requirements described above apply to this “Direct to Cloud” or “IoT” connection method.

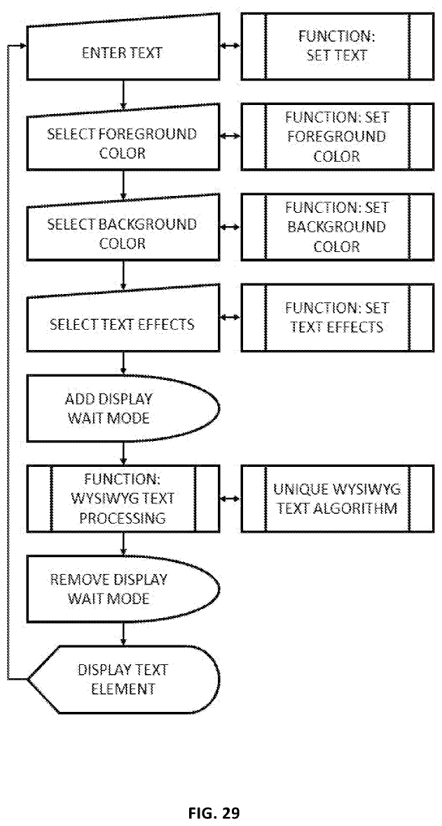

The user creates unique text strings and manipulates the text parameters look, feel and movement as outlined in the process flow in FIG. 29. The user sends the text using the Bluetooth Low Energy (BLE) Transceiver (32) on the Smart Device (30) to the Bluetooth Low Energy (BLE) Transceiver (42) on the Assembled Device (100) and the text is displayed on the Display System (60) using the unique WYSIWYG Text algorithm. Alternatively, the user sends the text using the Applications (15) on the Cloud Platform (10) or Applications (28) on the Advertisement Sharing Cloud Platform (20) to the Assembled Device (100) using the IEEE 802.11x (WIFI) Transceiver (46) on the Hardware System (40) to the Display System (60) using the unique WYSIWYG Text algorithm.

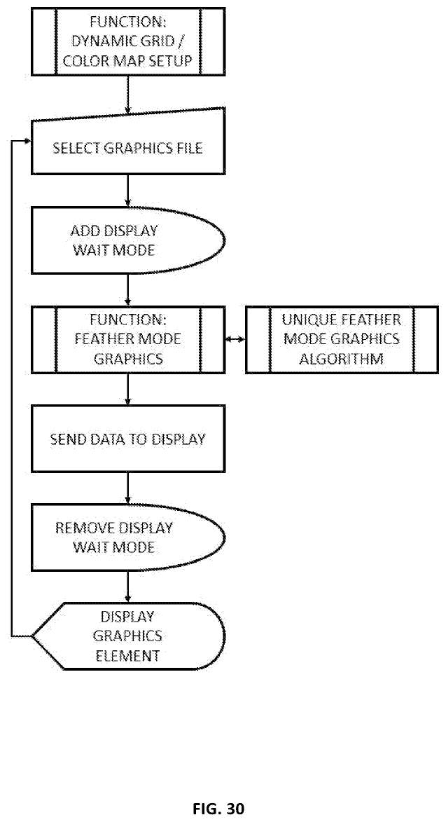

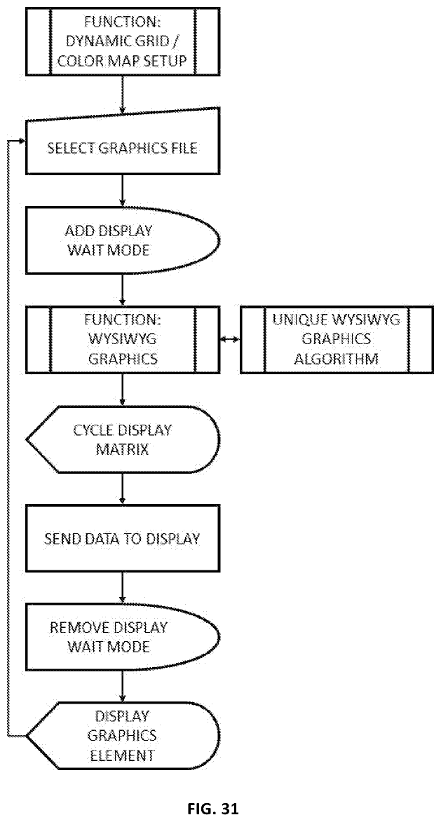

The user creates unique graphics in two ways. Firstly, by enter interactive graphics mode using the unique Feather Mode Graphics algorithm in the process flow outlined in FIG. 30, the user creates unique graphics and immediately in the background sends the graphics using the Bluetooth Low Energy (BLE) Transceiver (32) on the Smart Device (30) to the Bluetooth Low Energy (BLE) Transceiver (42) on the Assembled Device (100) and the text is displayed on the Display System (60). Secondly, the user creates graphics using the unique WYSIWYG Graphics algorithm in the process flow outlined in FIG. 31. The graphics can be saved in a standard graphics file format and stored locally on the Smart Device (30) and/or sent using the Bluetooth Low Energy (BLE) Transceiver (32) on the Smart Device (30) to the Bluetooth Low Energy (BLE) Transceiver (42) on the Assembled Device (100) and the graphics displayed on the Display System (60).

Alternatively, the user creates graphics by enter interactive graphics mode using the unique Feather Mode Graphics algorithm in the process flow outlined in FIG. 30, the user creates unique graphics and immediately in the background sends the graphics using the IEEE 802.11x (WIFI) Transceiver (46) on the Assembled Device (100) and the text is displayed on the Display System (60). The user can also create graphics using the unique WYSIWYG Graphics algorithm in the process flow outlined in FIG. 31, saves the graphics in a standard graphics file on the Cloud Platform (10) or Advertisement Sharing Cloud Platform (20) and/or sends graphics file using the Applications (15) on the Cloud Platform (10) or Applications (28) on the Advertisement Sharing Cloud Platform (20) to the Assembled Device (100) using the IEEE 802.11x (WIFI) Transceiver (46) on the Hardware System (40) to the Display System (60).

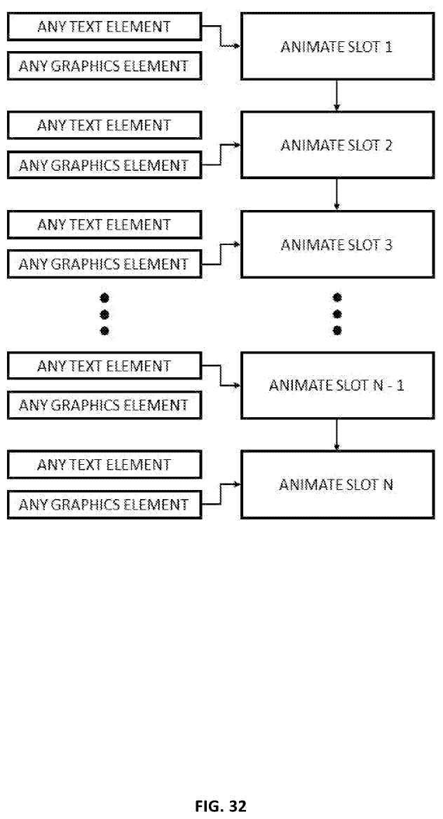

The user creates animated sequences of text and graphics as outlined in the process flow in FIG. 32. The user chooses a text or graphics element, display time duration, and physical properties of each element. The animation sequence of elements can range from 1 to N depending on the user's preference. Once completed, the user saves the animation in a standard animation file format and stores locally on the Smart Device (30) and/or sends using the Bluetooth Low Energy (BLE) Transceiver (32) on the Smart Device (30) to the Bluetooth Low Energy (BLE) Transceiver (42) on the Assembled Device (100) and the animation is displayed on the Display System (60). Alternatively, the user creates animations as outlined in FIG. 32, saves the animations in a standard animation file on the Cloud Platform (10) or Advertisement Sharing Cloud Platform (20) and/or sends animation file using the Applications (15) on the Cloud Platform (10) or Applications (28) on the Advertisement Sharing Cloud Platform (20) to the Assembled Device (100) using the IEEE 802.11x (WIFI) Transceiver (46) on the Hardware System (40) to the Display System (60).

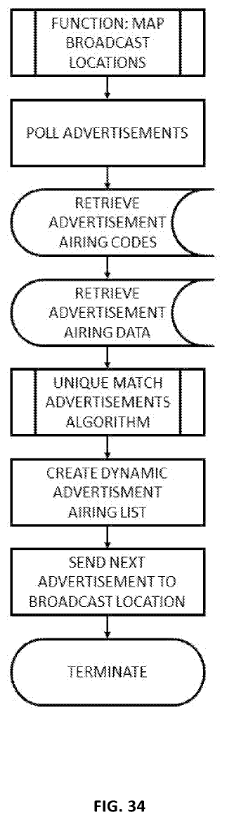

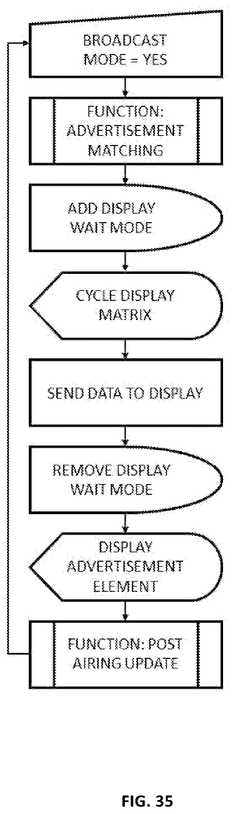

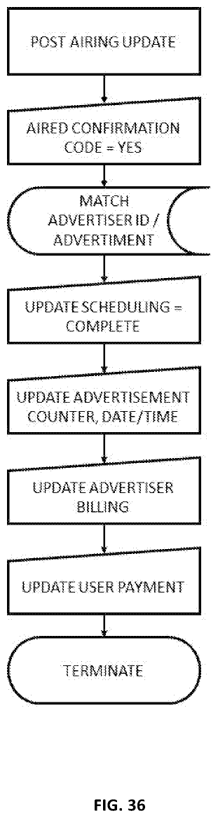

When the Assembled Device (100) is used in conjunction with the Advertisement Sharing Cloud System (20), the user can broadcast content on their Assembled Device (100) provided directly from the Advertisement Sharing Cloud System (20) as outlined in the process flow in FIG. 33. The user sets the local parameter Broadcast Mode=YES. The Advertisement Sharing Cloud System (20) periodically polls all registered Users (23) available on the network using IEEE 802.11x (WIFI) connection, retrieves the Users (23) current latitudinal and longitudinal position from the Geographical Positioning System (GPS) Transceiver (31) onboard the Smart Device (30) and the unique Map Broadcast Spots algorithm to create a dynamic list of potential broadcast locations. The Advertisement Sharing Cloud System (20) accesses the Advertisements (25) and user preferences from Users (23) to create a dynamic schedule of advertisements in Scheduling (26) for each available User (23) using a unique Match Advertisements algorithm to determine the dynamic list as outlined in the process flow in FIG. 34. The next advertisement in the dynamic list is send to the Assembled Device (100) using IEEE 802.11x (WIFI) connection. The Advertisement (25) is sent to the Display System (60) as illustrated in the process flow in FIG. 35. After the Advertisement (25) is aired on the Display System (60), an aired confirmation code is sent to the Advertisement Sharing Cloud System (20) using IEEE 802.11x (WIFI) connection as outlined in the process flow in FIG. 36. The Advertisement (25) is matched to the Advertiser (29) and the advertiser billing information is updated in Billing and Payments (27). The User (23) is confirmed and the user payment information is updated in the Billing and Payment (27). The Advertisements (25) is updated with the counter and date and time stamp. The Scheduling (26) is updated with the aired confirmation code.

The Assembled Device (100) can be temporarily mounted on a surface inside or outside a private or commercial vehicle to display text, graphics or animation. The Assembled Device (100) can be temporarily mounted on a surface inside or outside a private home, commercial business, office building or governmental office to display text, graphics or animation. The Assembled Device (100) can be temporarily mounted on a surface inside or outside a private or commercial marine vessel to display text, graphics or animation. The Assembled Device (100) can be temporarily mounted on a surface inside or outside a stadium, arena or venue to display text, graphics or animation. The Assembled Device (100) can be temporarily mounted on a surface of a private, commercial or government, fixed or temporary sign post, signage structure, poster or billboard to display text, graphics or animation. In all the above operational uses, one or more Display Extension Systems (50) and one or more Display Systems (60) can be added to the Assembled Device (100). In all the above operational uses, the Cloud Platform (10) can be replaced with the Advertisement Sharing Cloud Platform (20) to incorporate the additional functionality illustrated in FIG. 33-FIG. 36.

### M. Computing Environment

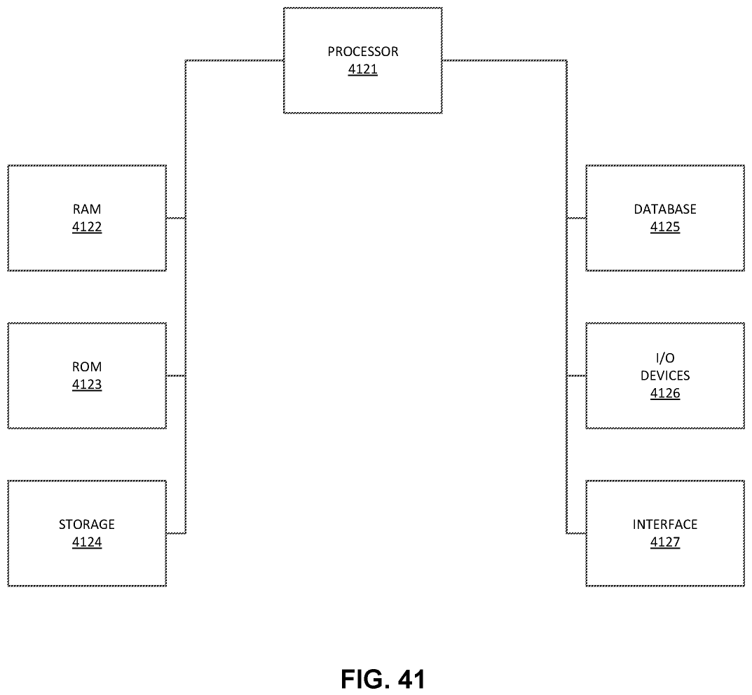

FIG. 41 illustrates an exemplary computer or computing device that can be used for some or all of the features described herein for sending and displaying content communicated between one or more pairs of sending and receiving devices configured in a dynamic communications network based on dynamic parameters shared between the devices at the time of transmission; processed on a miniaturized IOT device and rendered to a connected flexible display. All or a portion of the device shown in FIG. 41 may comprise all or a portion of any of the components described herein, including the cloud platform (10), the smart device (30), the hardware system (40), and/or the display system (60). As used herein, “computer” may include a plurality of computers. The computers may include one or more hardware components such as, for example, a processor 4121, a random access memory (RAM) module 4122, a read-only memory (ROM) module 4123, a storage 4124, a database 4125, one or more input/output (I/O) devices 4126, and an interface 4127. Alternatively and/or additionally, the computer may include one or more software components such as, for example, a computer-readable medium including computer executable instructions for performing a method associated with the exemplary embodiments. It is contemplated that one or more of the hardware components listed above may be implemented using software. For example, storage 4124 may include a software partition associated with one or more other hardware components. It is understood that the components listed above are exemplary only and not intended to be limiting.

Processor 4121 may include one or more processors, each configured to execute instructions and process data to perform one or more functions associated with a computer for distributing electronic messages (content) between a single or multiple pair of independent devices and displaying the content on the permanently connected display. Processor 4121 may be communicatively coupled to RAM 4122, ROM 4123, storage 4124, database 4125, I/O devices 4126, and interface 4127. Processor 4121 may be configured to execute sequences of computer program instructions to perform various processes. The computer program instructions may be loaded into RAM 4122 for execution by processor 4121.

RAM 4122 and ROM 4123 may each include one or more devices for storing information associated with operation of processor 4121. For example, ROM 4123 may include a memory device configured to access and store information associated with the computer, including information for identifying, initializing, and monitoring the operation of one or more components and subsystems. RAM 4122 may include a memory device for storing data associated with one or more operations of processor 4121. For example, ROM 4123 may load instructions into RAM 422 for execution by processor 4121.

Storage 4124 may include any type of mass storage device configured to store information that processor 4121 may need to perform processes corresponding with the disclosed embodiments. For example, storage 4124 may include one or more magnetic and/or optical disk devices, such as hard drives, CD-ROMs, DVD-ROMs, or any other type of mass media device.

Database 4125 may include one or more software and/or hardware components that cooperate to store, organize, sort, filter, and/or arrange data used by the computer and/or processor 4121. For example, database 4125 may store information and instructions related to messages to be displayed. It is contemplated that database 4125 may store additional and/or different information than that listed above.

I/O devices 4126 may include one or more components configured to communicate information with a user associated with computer. For example, I/O devices may include a console with an integrated keyboard and mouse to allow a user to maintain a database of display messages, graphics, and the like. I/O devices 4126 may also include a display including a graphical user interface (GUI) for outputting information on a monitor. I/O devices 4126 may also include peripheral devices such as, for example, a printer for printing information associated with the computer, a user-accessible disk drive (e.g., a USB port, a floppy, CD-ROM, or DVD-ROM drive, etc.) to allow a user to input data stored on a portable media device, a microphone, a speaker system, or any other suitable type of interface device.

Interface 4127 may include one or more components configured to transmit and receive data via a communication network, such as the Internet, a local area network, a workstation peer-to-peer network, a direct link network, a wireless network, or any other suitable communication platform. For example, interface 427 may include one or more modulators, demodulators, multiplexers, demultiplexers, network communication devices, wireless devices, antennas, modems, and any other type of device configured to enable data communication via a communication network.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications may be referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

### INDEX OF ELEMENTS

10: Cloud Platform
11: User Interface
12: Security
13: Users
14: Devices
15: Applications
20: Advertisement Sharing Cloud Platform
21: User Interface
22: Security
23: Users
24: Devices
25: Advertisements
26: Scheduling
27: Billing And Payments
28: Applications
29: Advertisers
30: Smart Device
31: Geographical Positioning System (gps) Transceiver
32: Bluetooth Low Energy (ble) Transceiver
33: Cellular Transceiver
34: Ieee 802.11x (WIFI) Transceiver
35: Mobile Application
40: Hardware System
41: Micro Controller Unit (mcu)
42: Bluetooth Low Energy (ble) Transceiver
43: Dc/dc Power Converter
44: Micro Universal Serial Bus (usb) Connector
45: Data Logic Shifter
46: Ieee 802.11x (WIFI) Transceiver
47: Spdt Power Switch
48: Printed Circuit Board (pcb)
49: Command And Control Program
50: Display Extension System
51: Dc/dc Power Converter
52: Male Display Extension Connection Port In
53: Male Display Extension Connection Port Out
54: Connection Cord In
55: Connection Cord Out
56: Printed Circuit Board (pcb)
57: Display Extension Hardware Case
60: Display System
61: Addressable Light Emitted Diode (led)
62: Conductive Medium
63: Display Array
64: Mounting Substrate A
65: Mounting Substrate B
66: Display Mounting System
67: Hardware System Wiring Interface Out
68: Hardware System Wiring Interface In
70: Smooth Surface Mount System
71: Combination End Cap And Mounting Interface
72: Standard End Cap And Mounting Interface
73: Top And Bottom Mounting Interface
74: External Mounting Interface
75: Keyhole Shaped Cutout
76: Clear Polyurethane Suction Cup
77: Female Hardware Connection Port In
78: Female Display Extension Connection Port Out
80: Metallic Surface Mount System
81: Standard End Cap
82: Magnetic Substrate
83: Female Hardware Connection Port In
84: Female Display Extension Connection Port Out
90: Hardware Case And Mount System
91: Standard Hardware Case
92: Hardware Connection Cord Out
93: Male Hardware Connection Port Out

What is claimed is:

1. A method for message distribution and display using an internet of things (IoT) message distribution and display platform, the method comprising:
receiving, by one or more portable internet of things (IoT) hardware devices, instructions and/or data from a cloud application residing on a cloud platform and/or a mobile software application residing on a smart device, wherein the cloud application and/or the mobile software application bi-directionally communicates with the one or more portable internet of things (IoT) hardware devices; and
displaying, on a Light-Emitted Diode (LED) array that is electrically connected to the one or more portable IoT hardware devices, text, graphics and animations that are self-generated or provided by another party, wherein the LED array is encased in a secure and permanent substrate and further comprises a mounting system;
wherein the text, graphics and animations that are self-generated or provided by another party are displayed based on the instructions and/or data from the cloud application and/or the mobile software application.

2. The method of claim 1, further comprising receiving may include remuneration and/or compensation for displaying the text, graphics and animations that are self-generated or provided by another party.

3. The method of claim 2, wherein the remuneration and/or compensation include fees and/or payments from a party requesting display of the content.

4. The method of any of claims 1-3, wherein the displaying text, graphics and animations can be self-generated and/or self-sourced text, graphics and animations (content), wherein display effects, and timing are governed by saved or interactive parameters available and controlled by a user.

5. The method of any of claims 1-4, wherein the displaying text, graphics and animations can be generated from other users, parties and/or sources on or outside of the cloud platform, wherein the display effects, and timing are governed by saved parameters included with the content to be displayed.

6. The method of any of claims 1-5, wherein the displaying text, graphics and animations utilizes saved or interactive user-defined parameters that control specific digital characteristics of the text, graphics and animations (content) including timing, duration, actions and characteristics of the content.

7. The method of any of claims 1-6, wherein the displaying text, graphics and animations utilizes an interface on which users interactively manipulate parameters to control the digital characteristics of the text, graphics and animations (content) including timing, duration, actions and characteristics of the content and where, when and how (scheduling) content is displayed.

8. The method of any of claims 1-7, wherein the displaying text, graphics and animations utilizes an interface on which users can interactively control parameters around scheduling the display of content immediately or in the future including using date, day and time parameters to control what date, days of the week and time of the day content is displayed; geographical and location parameters to control where content is displayed, wherein the location parameters include latitude, longitude, city, county, state, region, country, and whether content is displayed on a single or multiple display; and duration and frequency parameters to control a number of times the content is repeated and displayed on one or more displays.

9. The method of any of claims 2-7, wherein the remuneration and/or compensation, fees and/or payments calculations utilize a billing and payment matrix for the display of content based on geographic, time and business parameters; a content tracking and reconciliation schema, billing and payment engine; and an interactive user interface for scheduling, tracking, confirmation, payment and billing, and history.

10. The method of any of claims 1-9, wherein displayed text, graphics and animations tracks, logs and saves a history of all content displayed across the cloud platform identifying an entity that created and initiated the content display and a user that displayed the content, by user and over time for reporting, payment and billing, customer support and data mining purposes.

11. The method of any of claims 1-10, further comprising providing a security hardware architecture that protects all IoT software and hardware components, a security operating architecture for encrypting/unencrypting data packets, monitoring and controlling data integrity and packet traffic across the cloud platform.

12. The method of any of claims 1-11, wherein the Light-Emitted Diode (LED) array comprises a flexible, encapsulated, variable length and width, addressable light-emitted diode (LED) array.

13. The method of any of claims 1-12, further comprising configuring the Light-Emitted Diode (LED) array by changing a total count, spacing and placement parameters of addressable light-emitted diodes (LEDs) that comprise the LED array to varied totals and configurations based on end-application requirements.

14. The method of any of claims 1-13, further comprising configuring the secure and permanent substrate and mounting system by changing one or more of encapsulation substrate materials type, composition and parameters securing, encasing, protecting and supporting the addressable light-emitted diode (LED) array based on end-application requirements.

15. The method of any of claims 1-14, further comprising connecting power and data from multiple displays together thus resulting in a master/slave relationship wherein the data connection is shared and content is displayed seamlessly across multiple, disparate displays.

16. The method of any of claims 1-15, wherein the hardware, display and software operate at a low voltage and through on-board power shifting hardware to support multiple power sources, including standard wall and vehicle receptacles, and a range of battery voltages from 5V-24V.

17. The method of any of claims 1-16, wherein the LED array comprises a display power architecture that is scalable.

18. The method of any of claims 1-17, further comprising providing Internet of Things (IoT) Machine-2-Machine (M2M) communication capabilities, advanced networking capabilities and autonomous communication transceiver switching via on-board IEEE802.11x (WIFI) and Bluetooth Low Energy (BLE) transceivers.

19. The method of claim 1-18, wherein the one or more portable internet of things (IoT) hardware devices comprise a micro-controller unit (MCU) connected directly to the LED array and with Internet of Things (IoT) capability for the transmission and receipt of message packets (content and commands) via an on-board IEEE802.11x (WIFI) and/or Bluetooth Low Energy (BLE) transceiver.

20. The method of any of claims 1-19, wherein the mounting system comprises multiple integrated mounting systems each with the ability to mount temporarily to multiple external surfaces as dictated by end-application requirements.

21. The method of any of claims 1-20, further comprising wherein the IoT message distribution and display platform comprises an interconnecting display system that enables multiple individual IoT message distribution and display platforms to be linked together in width and/or in height directions to create a uniquely sized modular display assembly that functions as a single displaying unit.

22. The method of any of claims 1-21, wherein the IoT message distribution and display platform comprises a modular display assembly design that can increase the overall display area beyond a single display size based on end-application requirements.

23. The method of any of claims 1-22, wherein the IoT message distribution and display platform is used to display safety, distress, entertainment, logistics, information or other content on a non-rigid, portable display in any environment to achieve a specific need, goal or application.

24. The method of any of claims 1-23, wherein the IoT message distribution and display platform is used by individuals and/or businesses to display advertisements which are a sequenced combination of text, graphics and animation (content) on a non-rigid, portable display in any environment.

25. The method of any of claims 1-24, wherein the IoT message distribution and display platform provides a platform for individuals and other individuals and/or business to interact and transact based on multiple parameters with the intent to display text, graphics and animations (content) on a non-rigid, portable display in any environment for compensation and/or monetary fee.

26. The method of any of claims 1-25, wherein the mounting system is used to temporarily mount the display by using a unique suction cup mounting system supporting the weight of the display unit on a smooth surface; or a magnetic mounting system supporting the weight of the display unit on a metallic surface.

27. An internet of things (IoT) message distribution and display system, comprising:
a cloud application residing on a cloud platform or mobile software residing on a smart device; and
an internet of things (IoT) message distribution and display platform, said platform comprising:
one or more portable IoT hardware devices, wherein each of the one or more portable IoT hardware devices comprises a processor; and
a light-emitting diode (LED) array comprised of a plurality of interconnected individually-addressable LED elements, wherein the LED array is electrically connected to at least one of the one or more IoT hardware devices and wherein each LED element is addressable by the processor of the IoT hardware device, and wherein the processor is configured to:
receive instructions and/or data from the cloud application residing on the cloud platform and/or the mobile software application residing on the smart device, wherein the cloud application and/or the mobile software application bi-directionally communicates with the one or more portable internet of things (IoT) hardware devices; and
display on the LED array that is electrically connected to the one or more portable IoT hardware devices, text, graphics and animations that are self-generated or provided by another party, wherein the LED array is encased in a secure and permanent substrate and further comprises a mounting system,
wherein the text, graphics and animations that are self-generated or provided by another party are displayed based on the instructions and/or data from the cloud application and/or the mobile software application.

28. The system of claims 27, wherein the processor displaying text, graphics and animations can be self-generated and/or self-sourced text, graphics and animations (content) comprises the processor creating display effects and timing that are governed by saved or interactive parameters available and controlled by a user.

29. The system of any of claims 27-28, wherein the processor displaying text, graphics and animations can be generated from other users, parties and/or sources on or outside of the cloud platform, wherein the processor creating display effects and timing are governed by saved parameters included with the content to be displayed.

30. The system of any of claims 27-29, wherein the processor displaying text, graphics and animations utilizes the processor using saved or interactive user-defined parameters that control specific digital characteristics of the text, graphics and animations (content) including timing, duration, actions and characteristics of the content.

31. The system of any of claims 27-30, wherein the processor displaying text, graphics and animations utilizes an interface on which users interactively manipulate parameters to control the digital characteristics of the text, graphics and animations (content) including timing, duration, actions and characteristics of the content and where, when and how (scheduling) content is displayed.

32. The system of any of claims 27-31, wherein the processor displaying text, graphics and animations utilizes an interface on which users can interactively control parameters around scheduling the display of content immediately or in the future including using date, day and time parameters to control what date, days of the week and time of the day content is displayed; geographical and location parameters to control where content is displayed, wherein the location parameters include latitude, longitude, city, county, state, region, country, and whether content is displayed on a single or multiple display; and duration and frequency parameters to control a number of times the content is repeated and displayed on one or more displays.

33. The system of any of claims 31-32, wherein the interface is part of the smart device.

34. The system of any of claims 27-33, wherein the system tracks, logs and saves a history of all content displayed across the cloud platform identifying an entity that created and initiated the content display and a user that displayed the content, by user, and over time for reporting, payment and billing, customer support and data mining purposes.

35. The system of any of claims 27-34, further comprising a security hardware architecture that protects all IoT software and hardware components, a security operating architecture for encrypting/unencrypting data packets, monitoring and controlling data integrity and packet traffic across the cloud platform.

36. The system of any of claims 27-35, wherein the Light-Emitted Diode (LED) array comprises a flexible, encapsulated, variable length and width, addressable light-emitted diode (LED) array.

37. The system of any of claims 27-36, further comprising configuring the Light-Emitted Diode (LED) array by changing a total count, spacing and placement parameters of addressable light-emitted diodes (LEDs) that comprise the LED array to varied totals and configurations based on end-application requirements.

38. The system of any of claims 27-37, further comprising configuring the secure and permanent substrate and mounting system by changing one or more of encapsulation substrate materials type, composition and parameters securing, encasing, protecting and supporting the addressable light-emitted diode (LED) array based on end-application requirements.

39. The system of any of claims 27-38, further comprising connecting power and data from multiple displays together thus resulting in a master/slave relationship wherein the data connection is shared and content is displayed seamlessly across multiple, disparate displays.

40. The system of any of claims 27-39, wherein the hardware, display and software operate at a low voltage and through on-board power shifting hardware to support multiple power sources, including standard wall and vehicle receptacles, and a range of battery voltages from 5V-24V.

41. The system of any of claims 27-40, wherein the LED array comprises a display power architecture that is scalable.

42. The system of any of claims 27-41, further comprising providing Internet of Things (IoT) Machine-2-Machine (M2M) communication capabilities, advanced networking capabilities and autonomous communication transceiver switching via on-board IEEE802.11x (WIFI) and Bluetooth Low Energy (BLE) transceivers.

43. The system of claims 27-42, wherein the processor comprises a micro-controller unit (MCU) connected directly to the LED array and with Internet of Things (IoT) capability for the transmission and receipt of message packets (content and commands) via an on-board IEEE802.11x (WIFI) and/or Bluetooth Low Energy (BLE) transceiver.

44. The system of any of claims 27-43, wherein the mounting system comprises multiple integrated mounting systems each with the ability to mount temporarily to multiple external surfaces as dictated by end-application requirements.

45. The system of any of claims 27-44, wherein the system comprises an interconnecting display system that enables multiple individual IoT message distribution and display platforms to be linked together in width and/or in height directions to create a uniquely sized modular display assembly that functions as a single displaying unit.

46. The system of any of claims 27-45, wherein the IoT message distribution and display platform comprises a modular display assembly design that can increase the overall display area beyond a single display size based on end-application requirements.

47. The system of any of claims 27-46, wherein the IoT message distribution and display platform is used to display safety, distress, entertainment, logistics, information or other content on a non-rigid, portable display in any environment to achieve a specific need, goal or application.

48. The system of any of claims 27-47, wherein the IoT message distribution and display platform is used by individuals and/or businesses to display advertisements which are a sequenced combination of text, graphics and animation (content) on a non-rigid, portable display in any environment.

49. The system of any of claims 27-48, wherein the IoT message distribution and display platform provides a platform for individuals and other individuals and/or business to interact and transact based on multiple parameters with the intent to display text, graphics and animations (content) on a non-rigid, portable display in any environment for compensation and/or monetary fee.

50. The system of any of claims 27-49, wherein the mounting system is used to temporarily mount the display by using a unique suction cup mounting system supporting the weight of the display unit on a smooth surface; or a magnetic mounting system supporting the weight of the display unit on a metallic surface.
